(19) United States
(12) Patent Application Publication
(10) Pub. No.: US 2019/0006019 A1
(43) Pub. Date: Jan. 3, 2019

(54) WORD LINE LEAKAGE DETECTION USING SOURCE AND SINK CURRENTS

(71) Applicant: SanDisk Technologies LLC, Plano, TX (US)

(72) Inventors: Sung-En Wang, San Jose, CA (US); Jonathan Huynh, San Jose, CA (US)

(73) Assignee: SanDisk Technologies LLC, Plano, TX (US)

(21) Appl. No.: 15/636,287

(22) Filed: Jun. 28, 2017

(51) Int. Cl. G11C 29/02; G11C 16/28; G11C 16/30; G11C 29/50

(52) U.S. Cl. CPC G11C 29/025; G11C 16/28; G11C 2029/5006; G11C 29/50; G11C 16/30

(57) ABSTRACT

A leakage detection circuit is configured to generate a regulated voltage at a node and supply the regulated voltage to one or more word lines. The leakage detection circuit may adjust a source current used to regulate the voltage in response to leakage current sourced to the node. The leakage detection circuit may control an adjustable current sink connected to the node in order to maintain the source current within a target range. The leakage detection circuit may measure the amount of the leakage current by determining how much it had to adjust the leakage current amount to keep the source current within the target range.

### BACKGROUND

In a storage device, a memory array can have defects that occur during manufacturing of the storage device or during the operating life of the storage device. Defective word lines are one type of defect that can occur in the memory array. One way a word line can be defective is when there is a short between it and another component of the array, such as the substrate on which the memory array is located, or an adjacent or neighboring word line. Another way a word line can be defective is when the word line is broken. In many cases, data cannot be programmed into or read from memory cells connected a defective word line. As such, it may be desirable for the storage device to know ahead of time if word lines in a block are defective.

A short between a word line and another component of the memory array may cause leakage current to flow between the word line and the other component. Sensing for and measuring an amount of leakage current may indicate whether a word line is defective.

When performing a memory operation on a target set of memory cells, such as programming data into the target set of memory cells, verifying the programming of data into the target set of memory cells, or reading data from the target set of memory cells, certain word line voltages may be applied to selected word lines that are connected to the target set of memory cells. When a voltage is applied to a selected word line for performance of a memory operation, and that selected word line has a defect, leakage current resulting from defect generate an offset voltage that increases or decreases the level of the voltage applied to the selected word line. This offset voltage can lead to errors in the memory operation.

Some memory array configurations utilize sets of shared word lines, where word lines in the same shared set can receive the same voltage from the same voltage generator. In the event that one of the word lines in a shared set is defective and an offset voltage is generated as a result, that offset voltage may also be added to the voltage being applied to the other word lines of the shared set, regardless of whether those other word lines are defective. Ways to detect or measure word line leakage associated with memory operations performed on shared word lines may be desirable.

### BRIEF DESCRIPTION OF THE DRAWINGS

The accompanying drawings, which are incorporated in and constitute a part of this specification illustrate various aspects of the invention and together with the description, serve to explain its principles. Wherever convenient, the same reference numbers will be used throughout the drawings to refer to the same or like elements.

FIG. 1A is a block diagram of an exemplary non-volatile memory system.

FIG. 1B is a block diagram of a storage module that includes a plurality of non-volatile memory systems.

FIG. 1C is a block diagram of a hierarchical storage system.

FIG. 2A is a block diagram of exemplary components of a controller of the non-volatile memory system of FIG. 1A.

FIG. 2B is a block diagram of exemplary components of a non-volatile memory die of the non-volatile memory system of FIG. 1A.

FIG. 3 is a circuit diagram of an example floating gate transistor.

FIG. 4 is a graph of curves of drain-to-source current as a function of control gate voltage drawn through a floating gate transistor.

FIG. 5A is a block diagram of a plurality of memory cells organized into blocks.

FIG. 5B is a block diagram of a plurality of memory cells organized into blocks in different planes.

FIG. 6 is a circuit diagram of an example two-dimensional NAND-type flash memory array.

FIG. 7 is an example physical structure of a three-dimensional (3-D) NAND string.

FIG. 8 is an example physical structure of a U-shaped 3-D NAND string.

FIG. 9 is a cross-sectional view of a 3-D NAND memory array with U-shaped NAND strings in the y-z plane.

FIG. 10A is a cross-sectional view along the bit line direction (along the y-direction) of an example memory structure in which straight vertical NAND strings extend from common source connections in or near a substrate to global bit lines that extend over physical levels of memory cells.

FIG. 10B is a circuit diagram of separately-selectable sets of NAND strings of FIG. 10A.

FIG. 10C is a circuit diagram of a separately selectable set of NAND strings in cross section along the x-z plane.

FIG. 11A is a plot of threshold voltage distribution curves for memory cells storing two bits of data.

FIG. 11B is a plot of threshold voltage distribution curves for memory cells storing three bits of data.

FIG. 11C is a plot of threshold voltage distribution curves for memory cells storing four bits of data.

FIG. 12 is a schematic diagram of a leakage detection circuit.

FIG. 13 is a flow chart of an example method of performing a leakage current detection process.

FIG. 14 is a flow chart of an example method of determining usability statuses for a plurality of blocks based on leakage current detection.

### DETAILED DESCRIPTION

Overview

By way of introduction, the below embodiments relate to apparatuses, devices, circuit, systems, and methods for performing leakage current detection processes. In a first embodiment, a circuit includes a voltage generation circuit and a measurement circuit. The voltage generation circuit is configured to generate a voltage supplied to a word line of a memory array via a voltage supply path. The measurement circuit is configured to measure an amount of leakage current sourced to a node connected to the voltage supply path during supply of the voltage to the word line, and control an adjustable current sink to sink, from the node, an amount of sink current corresponding to the measured amount of the leakage current.

In some embodiments, the voltage generation circuit is further configured to supply a source current to the node, and regulate the voltage through adjustment of the level of the source current.

In some embodiments, the measurement circuit is configured to control the adjustable current sink to maintain a level of the source current in a target current range, and determine how much the adjustable current sink adjusted the sink current to keep the source current in the target current range in order to measure the amount of leakage current.

In some embodiments, a sense circuit is configured to sense an amount of the leakage current, and generate at least one sense current indicative of the amount of the leakage current. In addition, the measurement circuit is configured to measure the amount of the leakage current in response to the at least one sense current.

In some embodiments, the measurement circuit is further configured to compare the at least one sense current to a high reference current level and a low reference current level, and measure the amount of the leakage current in response to the comparison.

In some embodiments, the measurement circuit is further configured to control the adjustable current sink to increment and decrement the sink current in discrete step sizes in response to the comparison, and keep track of the incrementing and decrementing to measure the amount of the leakage current.

In some embodiments, the measurement circuit is further configured to control the adjustable current sink to adjust the sink current in discrete steps, and keep track of the adjustments to measure the amount of the leakage current.

In some embodiments, a control circuit is configured to identify that the leakage current has exceeded a threshold in response to the measurement.

In some embodiments, a control circuit is configured to identify a usability status of a block comprising the word line in response to the measured amount of leakage current.

In another embodiment, a circuit includes a voltage regulation circuit, a sense circuit, and a measurement circuit. The voltage regulation circuit is configured to supply a source current to a node for generation of a voltage supplied to a selected word line, and adjust the source current in response to a leakage current sourced to the node in order to regulate the voltage to a selected word line level. The sense circuit is configured to sense an adjustment of a level of the source circuit, and generate at least one sense current indicative of the adjustment. The measurement circuit is configured to measure an amount of the leakage current in response to the at least one sense current.

In some embodiments, the sense circuit includes a current mirror circuit configured to mirror the source current to generate the at least one sense current.

In some embodiments, the measurement circuit a comparison circuit and a logic circuit. The comparison circuit is configured compare the at least one sense current to a high reference current level and a low reference current level. The logic circuit is configured to adjust a quantified current amount of the leakage current based on the comparison.

In some embodiments, the logic circuit is further configured to control an adjustable current sink to maintain the source current between the high reference current level and the low reference current level, and determine the quantified current amount based on the control of the adjustable current sink.

In some embodiments, the logic circuit is configured to control the adjustable current sink in discrete steps.

In some embodiments, a control circuit is configured to identify that the leakage current has exceeded a threshold in response to the measurement.

In another embodiment, a system includes a memory that includes a first block and a second block, a voltage generation circuit, a measurement circuit, a control circuit, and a word line switching circuit. The voltage generation circuit is configured to concurrently supply a voltage to a first word line of the first block for performance of a first memory operation, and to a second word line of the second block for performance of a second memory operation. The measurement circuit is configured to measure an amount of leakage current generated during the concurrent supply of the voltage to the first word line and the second word line. The control circuit is configured to determine that an amount of the leakage current has exceeded a leakage current threshold. The word line switching circuit is configured to isolate the first word line and the second word line from each other in response to the determination that the amount of the leakage current exceeded the leakage current threshold, and supply the voltage to only one of the first word line and the second word line in response to the isolation. The control circuit is further configured to identify a usability status for each of the first block and the second block in response to the isolation.

In some embodiments, the voltage generation circuit is configured to supply a source current to a node to generate the voltage, and the measurement circuit is further configured to control an adjustable current sink to maintain the source current within a target current range during supply of the voltage to the first word line and the second word line, and keep track of adjustments to a sink current generated with the adjustable current sink to measure the amount of the leakage current.

In some embodiments, the voltage generation circuit includes a feedback path to adjust the source current.

In some embodiments, a sense circuit is configured to sense an adjustment of a level of the source current, and generate at least one sense current indicative of the adjustment. The measurement circuit is configured to measure the amount of the leakage current based on the at least one sense current.

In some embodiments, the voltage generation circuit is configured to concurrently supply the voltage to the first word line and to the second word line in response to one or more host commands to read or write data to memory cells connected to the first word line and to the second word line.

Other embodiments are possible, and each of the embodiments can be used alone or together in combination. Accordingly, various embodiments will now be described with reference to the attached drawings.

### Embodiments

The following embodiments describe apparatuses, devices, systems, and methods for performing leakage current detection processes. Before turning to these and other embodiments, the following paragraphs provide a discussion of exemplary memory systems and storage devices that can be used with these embodiments. Of course, these are just examples, and other suitable types of memory systems and/or storage devices can be used.

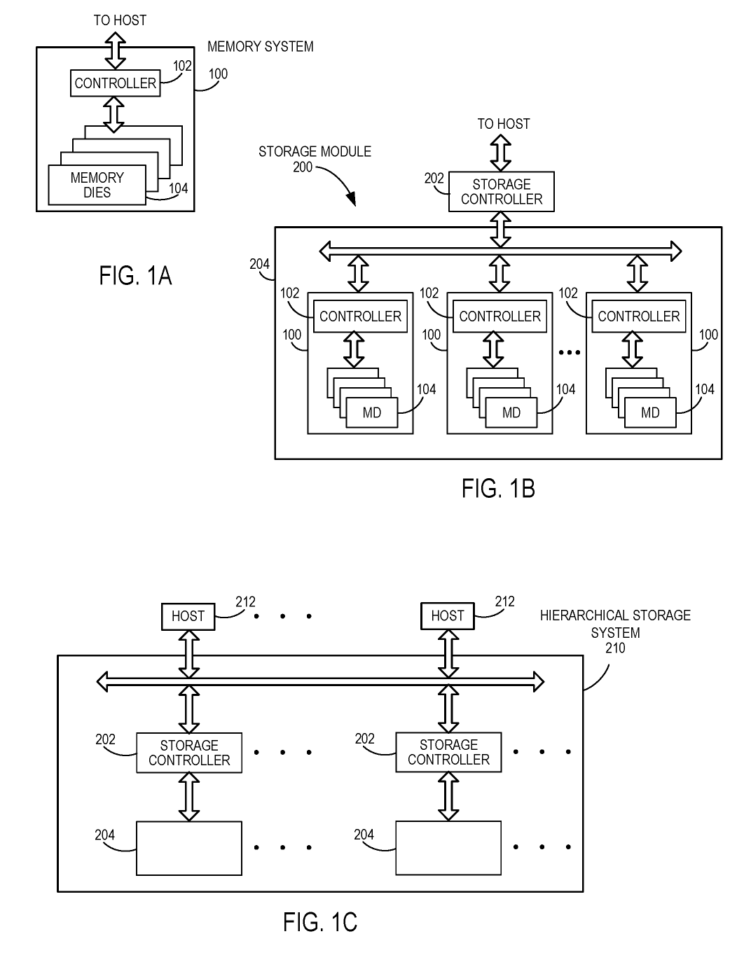

FIG. 1A is a block diagram illustrating a memory system 100. The memory system 100 may include a controller 102 and memory that may be made up of one or more memory dies 104. As used herein, the term die refers to the set of memory cells, and associated circuitry for managing the physical operation of those memory cells, that are formed on a single semiconductor substrate. The controller 102 may interface with a host system and transmit command sequences for read, program, and erase operations to the non-memory die(s) 104.

The controller 102 (which may be a flash memory controller) can take the form of processing circuitry, a microprocessor or processor, and a computer-readable medium that stores computer-readable program code (e.g., software or firmware) executable by the (micro)processor, logic gates, switches, an application specific integrated circuit (ASIC), a programmable logic controller, and an embedded microcontroller, for example. The controller 102 can be configured with hardware and/or firmware to perform the various functions described below and shown in the flow diagrams. Also, some of the components shown as being internal to the controller can also be stored external to the controller, and other components can be used. Additionally, the phrase “operatively in communication with” could mean directly in communication with or indirectly (wired or wireless) in communication with through one or more components, which may or may not be shown or described herein.

As used herein, the controller 102 is a device that manages data stored in the memory die(s) and communicates with a host, such as a computer or electronic device. The controller 102 can have various functionality in addition to the specific functionality described herein. For example, the controller 102 can format the memory dies 104 to ensure the it is operating properly, map out bad flash memory cells, and allocate spare cells to be substituted for future failed cells. Some part of the spare cells can be used to hold firmware to operate the controller 102 and implement other features. In operation, when a host needs to read data from or write data to the memory die(s) 104, the host will communicate with the controller 102. If the host provides a logical address to which data is to be read/written, the controller 102 can convert the logical address received from the host to a physical address in the memory die(s) 104. (Alternatively, the host can provide the physical address). The controller 102 can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

The interface between the controller 102 and the non-volatile memory die(s) 104 may be any suitable interface, such as flash interface, including those configured for Toggle Mode 200, 400, 800, 1000 or higher. For some example embodiments, the memory system 100 may be a card based system, such as a secure digital (SD) or a micro secure digital (micro-SD) card. In alternate example embodiments, the memory system 100 may be part of an embedded memory system.

In the example illustrated in FIG. 1A, the memory system 100 is shown as including a single channel between the controller 102 and the non-volatile memory die(s) 104. However, the subject matter described herein is not limited to memory systems having a single memory channel. For example, in some memory systems, such as those embodying NAND architectures, 2, 4, 8 or more channels may exist between the controller 102 and the memory die(s) 104, depending on controller capabilities. In any of the embodiments described herein, more than a single channel may exist between the controller and the memory die(s)s 104, even if a single channel is shown in the drawings.

FIG. 1B illustrates a storage module 200 that includes plural non-volatile memory systems 100. As such, the storage module 200 may include a storage controller 202 that interfaces with a host and with a storage system 204, which includes a plurality of non-volatile memory systems 100. The interface between the storage controller 202 and non-volatile memory systems 100 may be a bus interface, such as a serial advanced technology attachment (SATA), a peripheral component interface express (PCIe) interface, an embedded MultiMediaCard (eMMC) interface, a SD interface, or a Universal Serial Bus (USB) interface, as examples. The storage module 200, in one embodiment, may be a solid state drive (SSD), such as found in portable computing devices, such as laptop computers and tablet computers, and mobile phones.

FIG. 1C is a block diagram illustrating a hierarchical storage system 210. The hierarchical storage system 210 may include a plurality of storage controllers 202, each of which control a respective storage system 204. Host systems 212 may access memories within the hierarchical storage system 210 via a bus interface. Example bus interfaces may include a non-volatile memory express (NVMe), a fiber channel over Ethernet (FCoE) interface, an SD interface, a USB interface, a SATA interface, a PCIe interface, or an eMMC interface as examples. In one embodiment, the storage system 210 illustrated in FIG. 1C may be a rack mountable mass storage system that is accessible by multiple host computers, such as would be found in a data center or other location where mass storage is needed.

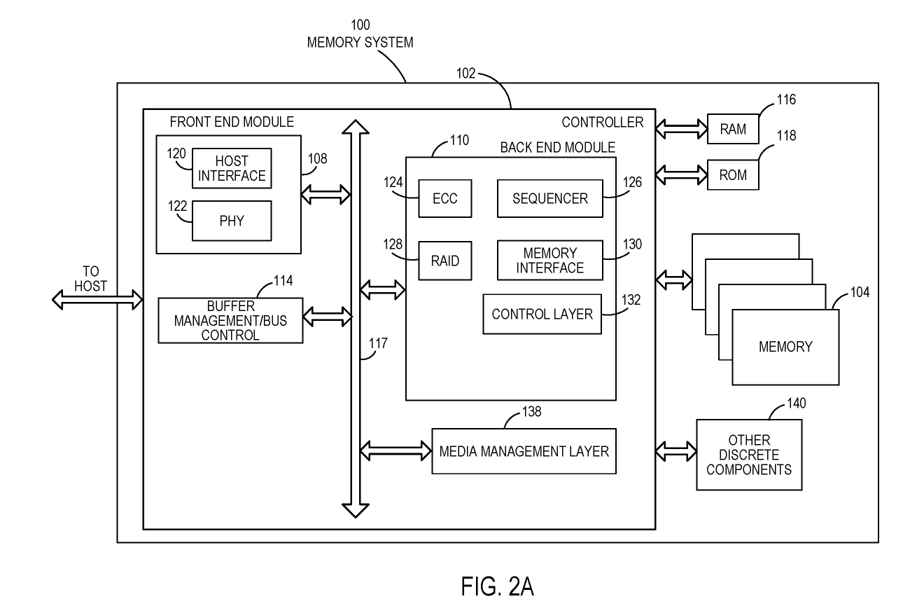

FIG. 2A is a block diagram illustrating exemplary components of the controller 102 in more detail. The controller 102 may include a front end module 108 that interfaces with a host, a back end module 110 that interfaces with the non-volatile memory die(s) 104, and various other modules that perform various functions of the non-volatile memory system 100. In general, a module may be hardware or a combination of hardware and software. For example, each module may include an application specific integrated circuit (ASIC), a field programmable gate array (FPGA), a circuit, a digital logic circuit, an analog circuit, a combination of discrete circuits, gates, or any other type of hardware or combination thereof. In addition or alternatively, each module may include memory hardware that comprises instructions executable with a processor or processor circuitry to implement one or more of the features of the module. When any one of the module includes the portion of the memory that comprises instructions executable with the processor, the module may or may not include the processor. In some examples, each module may just be the portion of the memory that comprises instructions executable with the processor to implement the features of the corresponding module without the module including any other hardware. Because each module includes at least some hardware even when the included hardware comprises software, each module may be interchangeably referred to as a hardware module.

The controller 102 may include a buffer manager/bus controller module 114 that manages buffers in random access memory (RAM) 116 and controls the internal bus arbitration for communication on an internal communications bus 117 of the controller 102. A read only memory (ROM) 118 may store and/or access system boot code. Although illustrated in FIG. 2A as located separately from the controller 102, in other embodiments one or both of the RAM 116 and the ROM 118 may be located within the controller 102. In yet other embodiments, portions of RAM 116 and ROM 118 may be located both within the controller 102 and outside the controller 102. Further, in some implementations, the controller 102, the RAM 116, and the ROM 118 may be located on separate semiconductor dies.

Additionally, the front end module 108 may include a host interface 120 and a physical layer interface (PHY) 122 that provide the electrical interface with the host or next level storage controller. The choice of the type of the host interface 120 can depend on the type of memory being used. Example types of the host interface 120 may include, but are not limited to, SATA, SATA Express, SAS, Fibre Channel, USB, PCIe, and NVMe. The host interface 120 may typically facilitate transfer for data, control signals, and timing signals.

The back end module 110 may include an error correction code (ECC) engine or module 124 that encodes the data bytes received from the host, and decodes and error corrects the data bytes read from the non-volatile memory die(s) 104. The back end module 110 may also include a command sequencer 126 that generates command sequences, such as program, read, and erase command sequences, to be transmitted to the non-volatile memory die(s) 104. Additionally, the back end module 110 may include a RAID (Redundant Array of Independent Drives) module 128 that manages generation of RAID parity and recovery of failed data. The RAID parity may be used as an additional level of integrity protection for the data being written into the non-volatile memory system 100. In some cases, the RAID module 128 may be a part of the ECC engine 124. A memory interface 130 provides the command sequences to the non-volatile memory die(s) 104 and receives status information from the non-volatile memory die(s) 104. Along with the command sequences and status information, data to be programmed into and read from the non-volatile memory die(s) 104 may be communicated through the memory interface 130. In one embodiment, the memory interface 130 may be a double data rate (DDR) interface and/or a Toggle Mode 200, 400, 800, or higher interface. A control layer 132 may control the overall operation of back end module 110.

Additional modules of the non-volatile memory system 100 illustrated in FIG. 2A may include a media management layer 138, which performs wear leveling of memory cells of the non-volatile memory die 104, address management, and facilitates folding operations as described in further detail below. The non-volatile memory system 100 may also include other discrete components 140, such as external electrical interfaces, external RAM, resistors, capacitors, or other components that may interface with controller 102. In alternative embodiments, one or more of the RAID module 128, media management layer 138 and buffer management/bus controller 114 are optional components that may not be necessary in the controller 102.

FIG. 2B is a block diagram illustrating exemplary components of a memory die 104 in more detail. The memory die 104 may include a memory cell structure 142 that includes a plurality of memory cells or memory elements. Any suitable type of memory can be used for the memory cells 142. As examples, the memory can be dynamic random access memory (“DRAM”) or static random access memory (“SRAM”), non-volatile memory, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory may have different configurations. For example, flash memory devices may be configured in a NAND or a NOR configuration.

The memory can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure.

In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in they direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

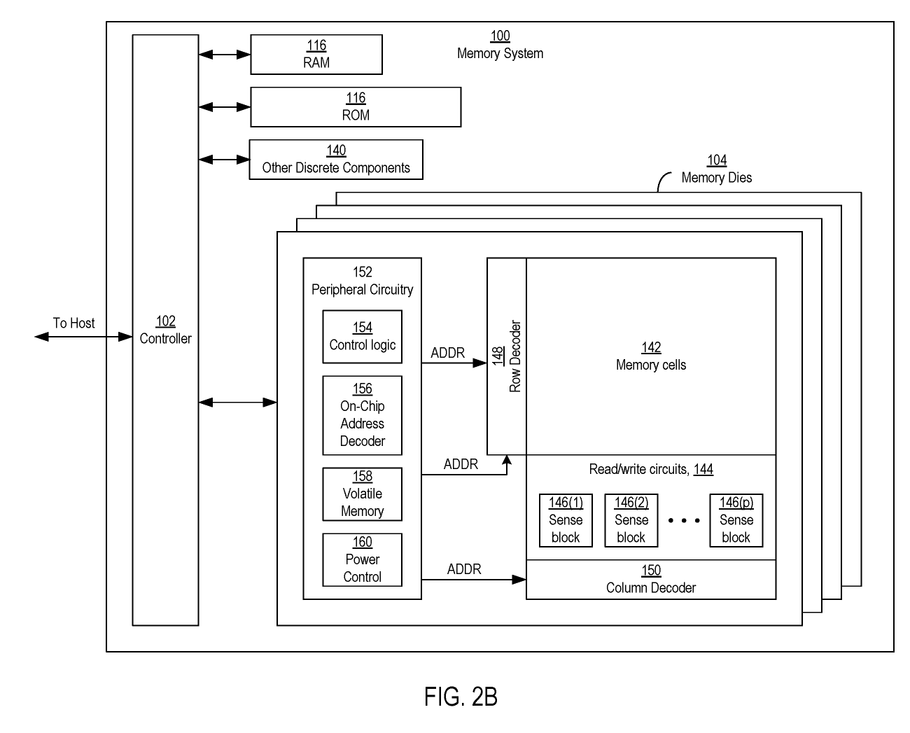

For some memory configurations, such as flash memory, a memory cell of the plurality of memory cells 142 may be a floating gate transistor (FGT). FIG. 3 shows a circuit schematic diagram of an example FGT 300. The FGT 300 may include a source 302, a drain 304, a control gate 306, a floating gate 308, and a substrate 310. The floating gate 308 may be surrounded by an insulator or insulating material that helps retain charge in the floating gate 308. The presence or absence of charges inside the floating gate 308 may cause a shift in a threshold voltage of the FGT, which is used to distinguish logic levels. For each given charge stored in the floating gate 308, a corresponding drain-to-source conduction current ID with respect to a fixed control gate Voltage VCG applied to the control gate 306 occurs. Additionally, the FGT 300 may have an associated range charges that can be programmable onto its floating gate 308 that define a corresponding threshold voltage window or a corresponding conduction current window. In this way, the FGT's threshold voltage may be indicative of the data stored in the memory cell.

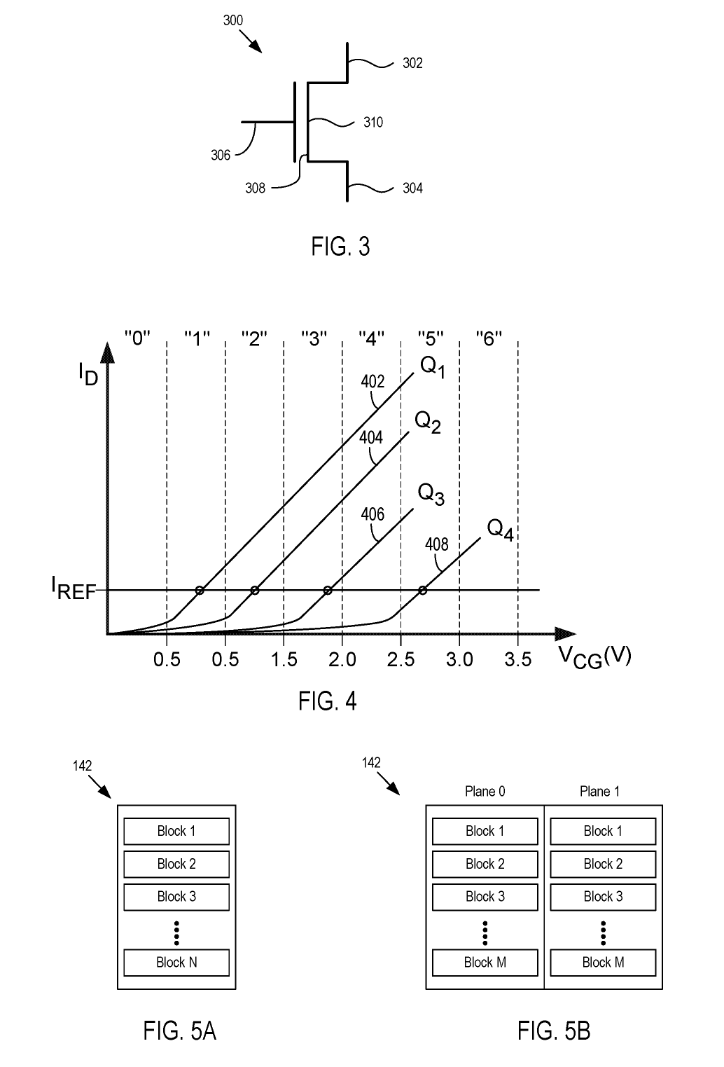

FIG. 4 is graph showing four curves 402, 404, 406, 408 of drain-to-source current ID drawn through the FGT 300 as a function of a control gate voltage VCG applied to the control gate 306. Each curve 402-408 corresponds to a respective one of four different charges or charge levels Q1, Q2, Q3, Q4 that the floating gate 308 can selectively store at any given time. Otherwise stated, the four curves 402-408 represent four possible charge levels that can be programmed on the floating gate 308 of the FGT 300, respectively corresponding to four possible memory states. In the example graph in FIG. 4, the threshold voltage window of a population of FGTs range from 0.5 volts (V) to 3.5 V. Seven possible memory states “0”, “1”, “2”, “3”, “4”, “5”, and “6” are defined or extend across the threshold voltage window, and respectively represent one erased states and six programmed states. The different states can be demarcated by partitioning the threshold voltage window into six regions of 0.5 V intervals. The FGT 300 may be in one of the states according to the charge stored in its floating gate 308 and where its drain-to-source current ID intersects a reference current IREF. For example, a FGT programmed to store charge Q1 in memory state “1” since its curve 402 intersects the reference current IREF in a region of the threshold voltage region demarcated by the control gate voltage VcG in a range from 0.5 V to 1.0 V. The more memory states the FGT 300 is programmed to store, the more finely divided are the regions defining the threshold voltage window. In some examples configurations, the threshold voltage window may extend from −1.5 V to 5 V, providing a maximum width of 6.5 V. If the FGT 300 can be programmed into any one of sixteen possible states, each state may occupy a respective region spanning 200 millivolts (mV) to 300 mV. The higher the resolution of the threshold voltage window (i.e., more states into which the FGT 300 can be programmed), the higher the precision that is needed in programming and reading operations to successfully read and write data. Further description of memory states and threshold voltages is provided in further detail below with respect to programming, program verify, and read operations.

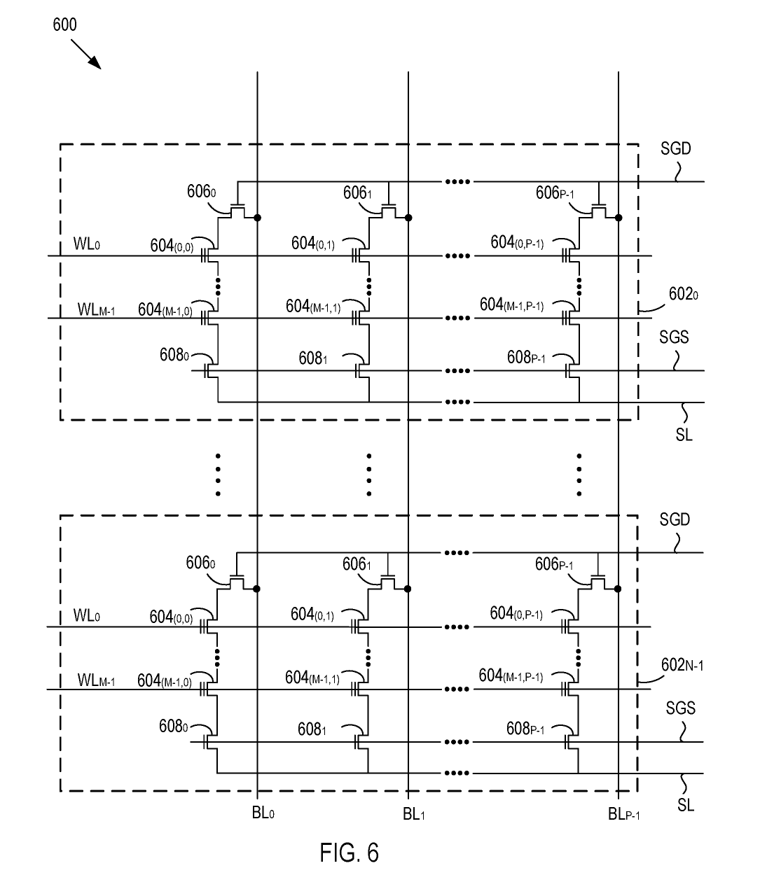

Referring to FIG. 5A, the memory cells 142 may be organized into an N-number of blocks, extending from a first block Block 1 to an Nth block Block N. Referring to FIG. 5B, for some example configurations, the N-number of blocks are organized into a plurality of planes. FIG. 5B shows an example configuration where the blocks are organized into two planes, including a first plane Plane 0 and a second plane Plane 1. Each plane is shown as included an M-number of blocks, extending from a first block Block 1 to an Mth block Block M. Data stored in different planes may be sensed simultaneously or independently.

For configurations where the memory cells are organized into a two-dimensional array, the memory cells may be configured in a matrix-like structure of rows and columns in each of the blocks. At the intersection of a row and a column is a memory cell. A column of memory cells is a referred to as a string, and memory cells in a string are electrically connected in series. A row of memory cells is referred to as a page. Where the memory cells are FGTs, control gates of FGTs in a page or row may be electrically connected together.

Additionally, each of the blocks includes word lines and bit lines connected to the memory cells. Each page of memory cells is coupled to a word line. Where the memory cells are FGTs, each word line may be coupled to the control gates of the FGTs in a page. In addition, each string of memory cells is coupled to a bit line. Further, a single string may span across multiple word lines, and the number of memory cells in a string may be equal to the number of pages in a block.

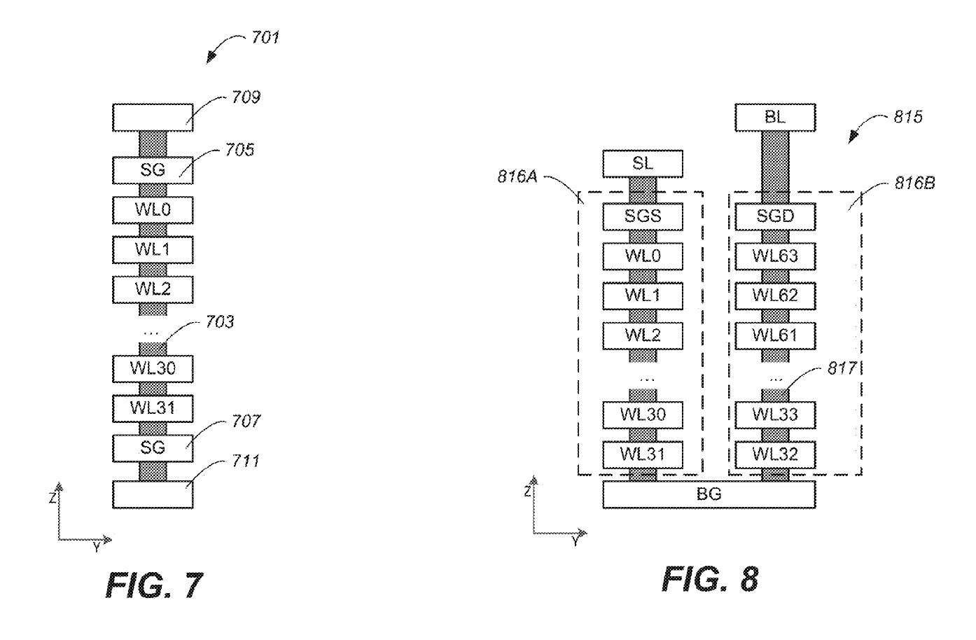

FIG. 6 is a circuit schematic diagram of at least a portion of an exemplary two-dimensional NAND-type flash memory array 600, which may be representative of at least a portion of the plurality of memory cells 142. For example, the memory array 600 may be representative of a single plane of blocks on a memory die 104. The memory array 600 may include an N-number of blocks 602₀ to 602_{N-1}. Each block 602 includes a P-number of strings of FGTs 604, with each string coupled to respective one of a P-number of bit lines BL₀ to BL_{P-1}. Additionally, each block 602 includes an M-number of pages of FGTs 604, with each page coupled to a respective one of an M-number of word lines WL₀ to WL_{M-1}. Each ith, jth FGT(i,j) of a given block 602 is connected to an ith word lineWLᵢ and to a jth bit line BLⱼ of the given block. As shown in FIG. 6, bit lines BL₀ to BL_{P-1} are shared among the blocks 602₀ to 602_{N-1} may be which are shared among the blocks, such as blocks within the same plane.

Within each block 602, each string is connected at one end to an associated drain select gate transistor 606, and each string is coupled to its associated bit line BL via the associated drain select gate transistor 606. Switching of the drain select gate transistors 606₀ to 606_{P-1} may be controlled using a drain select gate bias line SGD that supplies a drain select gate bias voltage V_{SGD} to turn on and off the drain select transistors 606₀ to 606_{P-1}. In addition, within each block 602, each string is connected at its other end to an associated source select gate transistor 608, and each string is coupled to a common source line SL via the associated source select gate transistor 608. Switching of the source select gate transistors 608₀ to 608_{P-1} may be controlled using a source select gate bias line SGS that supplies a source select gate bias voltage V_{SGS} to turn on and off the source select transistors 608₀ to 608_{P-1}. Also, although not shown, in some cases, dummy word lines, which contain no user data, can also be used in the memory array 600 adjacent to the source select gate transistors 608₀ to 608_{P-1}. The dummy word lines may be used to shield edge word lines and FGTs from certain edge effects.

An alternative arrangement to a conventional two-dimensional (2-D) NAND array is a three-dimensional (3-D) array. In contrast to 2-D NAND arrays, which are formed along a planar surface of a semiconductor wafer, 3-D arrays extend up from the wafer surface and generally include stacks, or columns, of memory cells extending upwards. Various 3-D arrangements are possible. In one arrangement a NAND string is formed vertically with one end (e.g. source) at the wafer surface and the other end (e.g. drain) on top. In another arrangement a NAND string is formed in a U-shape so that both ends of the NAND string are accessible on top, thus facilitating connections between such strings.

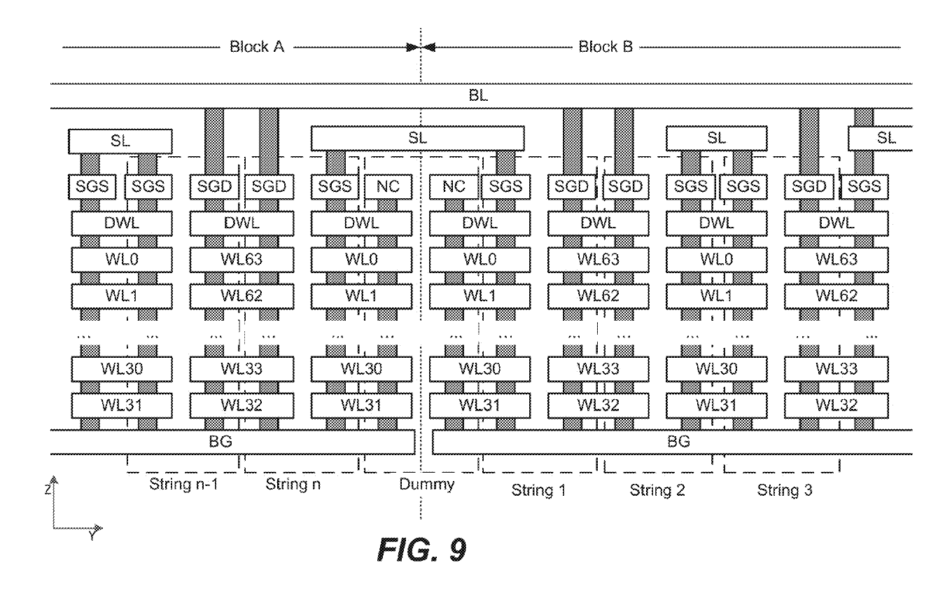

FIG. 7 shows a first example of a NAND string 701 that extends in a vertical direction, i.e. extending in the z-direction, perpendicular to the x-y plane of the substrate. Memory cells are formed where a vertical bit line (local bit line) 703 passes through a word line (e.g. WL0, WL1, etc.). A charge trapping layer between the local bit line and the word line stores charge, which affects the threshold voltage of the transistor formed by the word line (gate) coupled to the vertical bit line (channel) that it encircles. Such memory cells may be formed by forming stacks of word lines and then etching memory holes where memory cells are to be formed. Memory holes are then lined with a charge trapping layer and filled with a suitable local bit line/channel material (with suitable dielectric layers for isolation).

As with two-dimensional (planar) NAND strings, select gates 705, 707, are located at either end of the string to allow the NAND string to be selectively connected to, or isolated from, external elements 709, 711. Such external elements are generally conductive lines such as common source lines or bit lines that serve large numbers of NAND strings. Vertical NAND strings may be operated in a similar manner to planar NAND strings and both Single Level Cell (SLC) and Multi Level Cell (MLC) operation is possible. While FIG. 7 shows an example of a NAND string that has 32 cells (0-31) connected in series, the number of cells in a NAND string may be any suitable number. Not all cells are shown for clarity. It will be understood that additional cells are formed where word lines 3-29 (not shown) intersect the local vertical bit line.

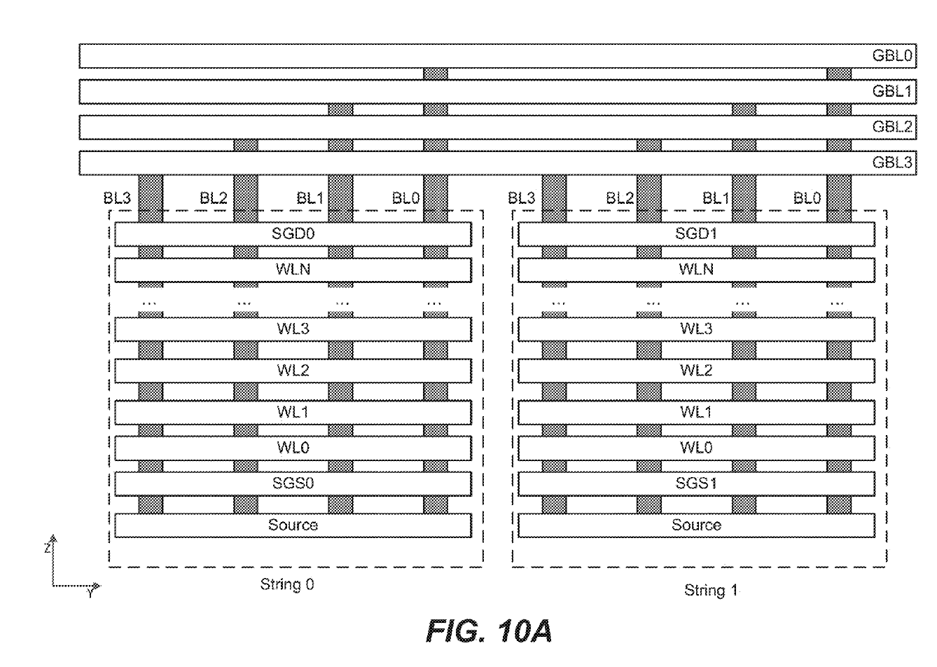

FIG. 8 shows a second example of a NAND string 815 that extends in a vertical direction (z-direction). In this case, NAND string 815 forms a U-shape, connecting with external elements (source line “SL” and bit line “BL”) located on the top of the structure. At the bottom of NAND string 815 is a controllable gate (back gate “BG”) which connects the two wings 816A, 816B of NAND string 815. A total of 64 cells are formed where word lines WL0-WL63 intersect the vertical local bit line 817 (though in other examples other numbers of cells may be provided). Select gates SGS, SGD, are located at either end of NAND string 815 to control connection/isolation of NAND string 815.

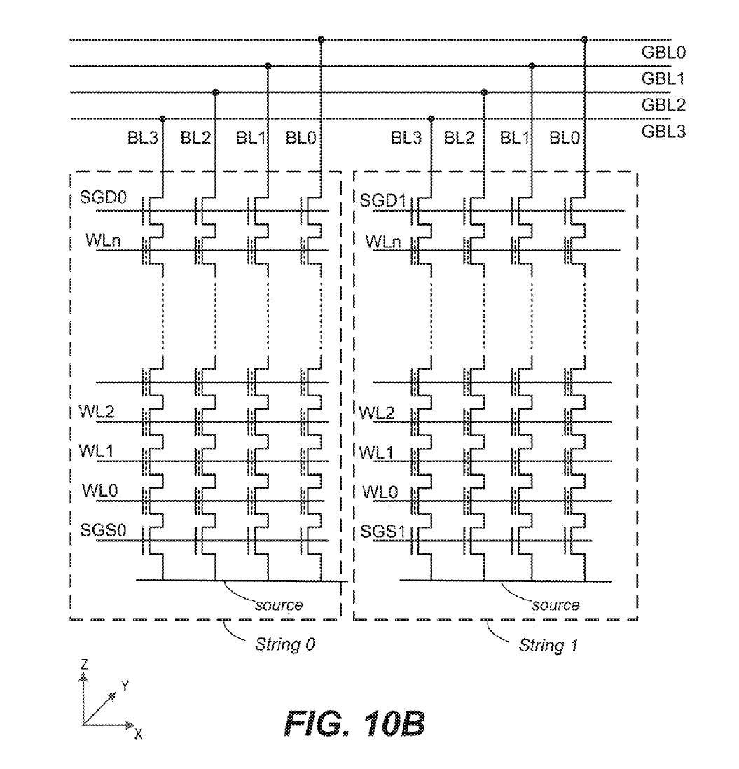

Vertical NAND strings may be arranged to form a 3-D NAND array in various ways. FIG. 9 shows an example where multiple U-shaped NAND strings in a block are connected to a bit line. In this case, there are n separately-selectable sets of strings (String 1-String n) in a block connected to a bit line (“BL”). The value of “n” may be any suitable number, for example, 8, 12, 16, 32, or more. Strings alternate in orientation with odd numbered strings having their source connection on the left, and even numbered strings having their source on the right. This arrangement is convenient but is not essential and other patterns are also possible.

Common source lines “SL” connect to one end of each NAND string (opposite to the end that connects to the bit line). This may be considered the source end of the NAND string, with the bit line end being considered as the drain end of the NAND string. Common source lines may be connected so that all source lines for a block may be controlled together by a peripheral circuit. Thus, NAND strings of a block extend in parallel between bit lines on one end, and common source lines on the other end.

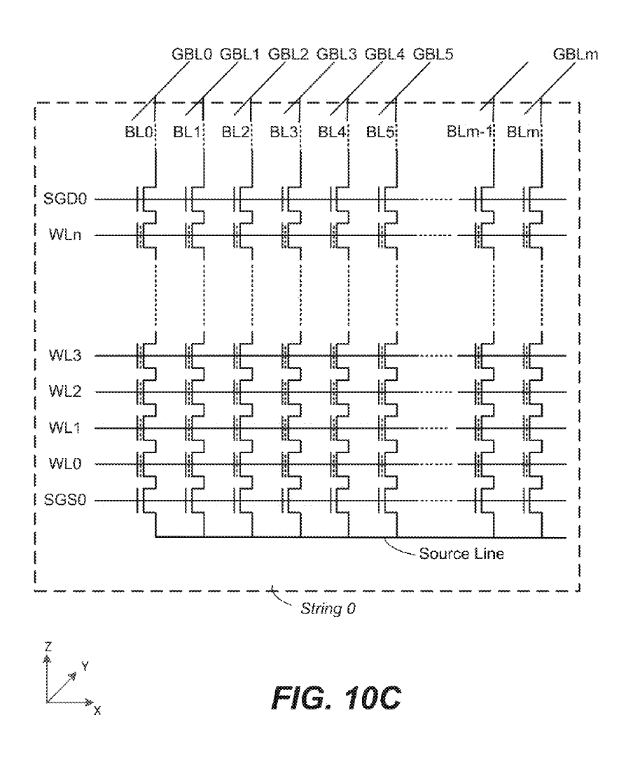

FIG. 10A shows a memory structure, in cross section along the bit line direction (along y-direction) in which straight vertical NAND strings extend from common source connections in or near a substrate to global bit lines (GBL0-GBL3) that extend over the physical levels of memory cells. Word lines in a given physical level in a block are formed from a sheet of conductive material. Memory hole structures extend down through these sheets of conductive material to form memory cells that are connected in series vertically (along the z-direction) by vertical bit lines (BL0-BL3) to form vertical NAND strings. Within a given block there are multiple NAND strings connected to a given global bit line (e.g. GBL0 connects with multiple BL0s). NAND strings are grouped into sets of strings that share common select lines. Thus, for example, NAND strings that are selected by source select line SGSO and drain select line SGD0 may be considered as a set of NAND strings and may be designated as String 0, while NAND strings that are selected by source select line SGS1 and drain select line SGD1 may be considered as another set of NAND strings and may be designated as String 1 as shown. A block may consist of any suitable number of such separately-selectable sets of strings. It will be understood that FIG. 10A shows only portions of GBL0 GBL3, and that these bit lines extend further in the y-direction and may connect with additional NAND strings in the block and in other blocks. Furthermore, additional bit lines extend parallel to GBL0 GBL3 (e.g. at different locations along x-axis, in front of, or behind the location of the cross-section of FIG. 10A).

FIG. 10B illustrates separately-selectable sets of NAND strings of FIG. 10A schematically. It can be seen that each of the global bit lines (GBL0-GBL3) is connected to multiple separately selectable sets of NAND strings (e.g. GBL0 connects to vertical bit line BL0 of String 0 and also connects to vertical bit line BL0 of String 1) in the portion of the block shown. In some cases, word lines of all strings of a block are electrically connected, e.g. WL0 in string 0 may be connected to WL0 of String 1, String 2, etc. Such word lines may be formed as a continuous sheet of conductive material that extends through all sets of strings of the block. Source lines may also be common for all strings of a block. For example, a portion of a substrate may be doped to form a continuous conductor underlying a block. Source and drain select lines are not shared by different sets of strings so that, for example, SGD0 and SGSO can be biased to select String 0 without similarly biasing SGD1 and SGS1. Thus, String 0 may be individually selected (connected to global bit lines and a common source) while String 1 (and other sets of strings) remain isolated from global bit lines and the common source. Accessing memory cells in a block during programming and reading operations generally includes applying select voltages to a pair of select lines (e.g. SGSO and SGD0) while supplying unselect voltages to all other select lines of the block (e.g. SGS1 and SGD1). Then, appropriate voltages are applied to word lines of the block so that a particular word line in the selected set of strings may be accessed (e.g. a read voltage is applied to the particular word line, while read-pass voltages are applied to other word lines). Erasing operations may be applied on an entire block (all sets of strings in a block) rather than on a particular set of strings in a block.

FIG. 10C shows a separately selectable set of NAND strings, String 0, of FIGS. 10A-B in cross section along the X-Z plane. It can be seen that each global bit line (GBL0-GBLm) is connected to one vertical NAND string (vertical bit line BL0-BLm) in String 0. String 0 may be selected by applying appropriate voltages to select lines SGD0 and SGSO. Other sets of strings are similarly connected to global bit lines (GBL0-GBLm) at different locations along the Y direction and with different select lines that may receive unselect voltages when String 0 is selected.

Referring back to FIG. 2B, the memory die 104 may further include read/write circuits 144 that includes a plurality or p-number of sense blocks (also referred to as sense modules or sense circuits) 146. As described in further detail below, the sense blocks 146 are configured to participate in reading or programming a page of memory cells in parallel.

The memory die 104 may also include a row address decoder 148 and a column address decoder 150. The row address decoder 148 may decode a row address and select a particular word line in the memory array 142 when reading or writing data to/from the memory cells 142. The column address decoder 150 may decode a column address to select a particular group of bitlines in the memory array 142 to read/write circuits 144.

In addition, the non-volatile memory die 104 may include peripheral circuitry 152. The peripheral circuitry 152 may include control logic circuitry (or simply control circuit) 154, which may be implemented as a state machine, that provides on-chip control of memory operations as well as status information to the controller 102. The peripheral circuitry 152 may also include an on-chip address decoder 156 that provides an address interface between addressing used by the controller 102 and/or a host and the hardware addressing used by the row and column decoders 148, 150. In addition, the peripheral circuitry 152 may also include volatile memory 158. An example configuration of the volatile memory 158 may include latches, although other configurations are possible.

In addition, the peripheral circuitry 152 may include power control circuitry 160 that is configured to generate and supply voltages to the memory array 142, including voltages (including program voltage pulses) to the wordlines, erase voltages (including erase voltage pulses), the source select gate bias voltage V_{SSG} to the source select gate bias line SSG, the drain select gate bias voltage V_{BSG} to the drain select gate bias line DSG, a cell source voltage V_{celsrc} on the source lines SL, as well as other voltages that may be supplied to the memory array 142, the read/write circuits 144, including the sense blocks 146, and/or other circuit components on the memory die 104. The various voltages that are supplied by the power control circuitry 160 are described in further detail below. The power control circuitry 160 may include any of various circuit topologies or configurations to supply the voltages at appropriate levels to perform the read, write, and erase operations, such as driver circuits, charge pumps, reference voltage generators, and pulse generation circuits, or a combination thereof. Other types of circuits to generate the voltages may be possible. In addition, the power control circuitry 160 may communicate with and/or be controlled by the control logic circuitry 154, the read/write circuits 144, and/or the sense blocks 146 in order to supply the voltages at appropriate levels and appropriate times to carry out the memory operations.

In order to program a target memory cell, and in particular a FGT, the power control circuitry 160 applies a program voltage to the control gate of the memory cell, and the bit line that is connected to the target memory cell is grounded, which in turn causes electrons from the channel to be injected into the floating gate. During a program operation, the bit line that is connected to the target memory cell is referred to as a selected bit line. Conversely, a bit line that is not connected to a target memory cell during a program operation is referred to as an unselected bit line. In this context, a state of the bit line may refer to whether the bit line is selected or unselected. Otherwise stated, a bit line can be in one of two states, selected or unselected. When electrons accumulate in the floating gate, the floating gate becomes negatively charged and the threshold voltage V_{TH} of the memory cell is raised. The power control circuitry 160 applies the program voltage V_{PGM} on the wordline that is connected to the target memory cell in order for the control gate of the target memory cell to receive the program voltage V_{PGM} and for the memory cell to be programmed. As previously described, in a block, one memory cell in each of the NAND strings share the same word line. During a program operation, the word line that is connected to a target memory cell is referred to as a selected word line. Conversely, a word line that is not connected to a target memory cell during a program operation is referred to as an unselected word line.

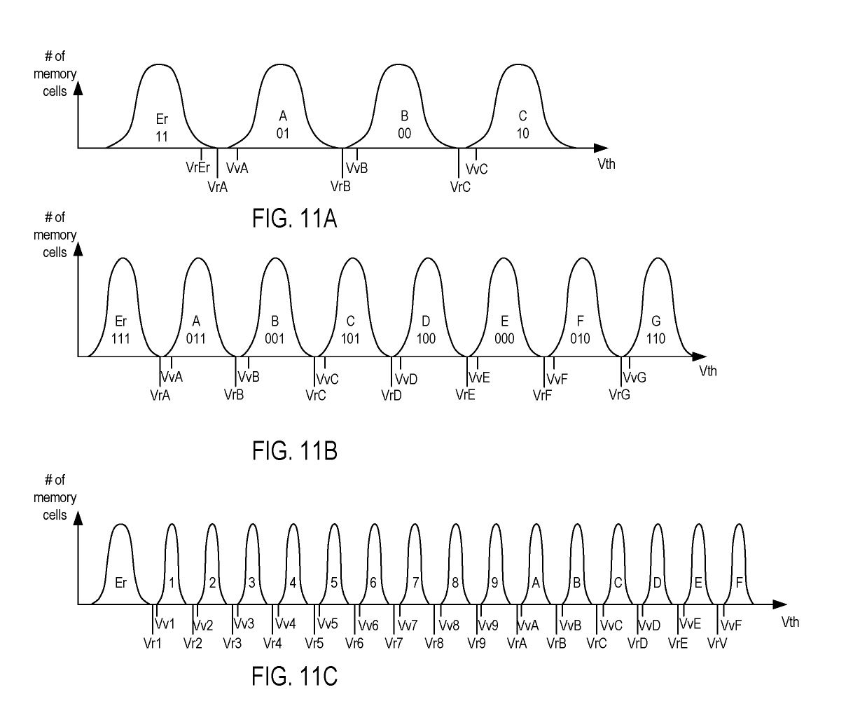

FIGS. 11A-11C are plots of threshold voltage distribution curves for different numbers of bits being stored the memory cells. The threshold voltage distribution curves are plotted for threshold voltage V_{TH} as a function of the number of memory cells. FIG. 11A show threshold voltage distribution curves for memory cells programmed to store two bits of data, FIG. 11B show threshold voltage distribution curves for memory cells programmed to store three bits of data, and FIG. 11C show voltage distribution curves for memory cells programmed to store four bits of data. Similar threshold voltage distribution curves may be generated for memory cells programmed to store numbers of bits other than two, three, and four.

At a given point in time, each memory cell may be a particular one of a plurality of memory states (otherwise referred to as a data state). The memory states may include an erased stated and a plurality of programmed states. Accordingly, at a given point in time, each memory cell may be in the erased state or one of the plurality of programmed states. The number of programmed states corresponds to the number of bits the memory cells are programmed to store. With reference to FIG. 11A, for a memory cell programmed to store two bits, the memory cell may be in an erased state Er or one of three programmed states A, B, C. With reference to FIG. 11B, for a memory cell programmed to store three bits, the memory cell may be in an erased state Er or one of seven programmed states A, B, C, D, E, F, G. With reference to FIG. 11C, for a memory cell programmed to store four bits, the memory cell may be in an erased state Er or one of fifteen programmed states 1, 2, 3, 4, 5, 6, 7, 8, 9, A, B, C, D, E, F. As shown in FIGS. 11A-11C, each voltage distribution curve is associated with the erased state or one of the programmed states.

Additionally, each threshold voltage distribution curve defines and/or is associated with a distinct threshold voltage range that, in turn, defines, is assigned, or is associated with a distinct one of a plurality of predetermined n-bit binary values. As such, determining what threshold voltage V_{TH} a memory cell has allows the data (i.e., the logic values of the bits) that the memory cell is storing to be determined. The specific relationship between the data programmed into the memory cells and the threshold voltage levels of the memory cell depends on the data encoding scheme used for programming the memory cells. In one example, as shown in FIGS. 11A and 11B, a Gray code scheme is used to assign data values to the threshold voltage distribution curves. Under this scheme, for memory cells programmed with two bits of data, the data value “11” is assigned to the range of threshold voltages associated with the erased state Er, the data value “01” is assigned to the range of threshold voltages associated with programmed state A, the data value “00” is assigned to the range of threshold voltages associated with programmed state B, and the data value “10” is assigned to the range of threshold voltages associated with the programmed state C. Similar relationships between data values and memory states can be made for memory cells programmed to store three bits, four bits, or other bits of data.

Prior to performance of a program operation that programs a plurality or group of target memory cells, all of the memory cells of the group subjected to and/or selected to be programmed in the programming operation may be in the erased state. During the programming operation, the power control circuitry 160 may apply the program voltage to a selected word line and in turn the control gates of the target memory cells as a series of program voltage pulses. The target memory cells being programmed concurrently are connected to the same, selected word line. In many programming operations, the power control circuitry 160 increases the magnitude of the program pulses with each successive pulse by a predetermined step size. Also, as described in further detail below, the power control circuitry 160 may apply one or more verify pulses to the control gate of the target memory cell in between program pulses as part of a program loop or a program-verify operation. Additionally, during a programming operation, the power control circuitry 160 may apply one or more boosting voltages to the unselected word lines.

The target memory cells connected to the selected word line will concurrently have their threshold voltage change, unless they have been locked out from programming. When the programming operation is complete for one of the target memory cells, the target memory cell is locked out from further programming while the programming operation continues for the other target memory cells in subsequent program loops. Also, for some example programming operations, the control logic circuitry 154 may maintain a counter that counts the program pulses.

During a program operation to program a group of target memory cells, each target memory cell is assigned to one of the plurality of memory states according to write data that is to be programmed into the target memory cells during the program operation. Based on its assigned memory state, a given target memory cell will either remain the erased state or be programmed to a programmed state different from the erased state. When the control logic 154 receives a program command from the controller 102, or otherwise determines to perform a program operation, the write data in stored in latches included in the read/write circuitry 144. During the programming operation, the read/write circuitry 144 can read the write data to determine the respective memory state to which each of the target memory cells is to be programmed.

As described in further detail below, and as illustrated in FIGS. 11A-11C, each programmed state is associated with a respective verify voltage level V_{V}. A given target memory cell is programmed in its assigned memory state when its threshold voltage V_{TH} is above the verify voltage V_{V} associated with the memory state assigned to that target memory cell. As long as the threshold voltage V_{TH} of the given target memory cell is below the associated verify voltage V_{V}, the control gate of the target memory cell may be subject to a program pulse to increase the target memory cell's threshold voltage V_{TH} to within the threshold voltage range associated with the memory state assigned to the given target memory cell. Alternatively, when the threshold voltage V_{TH} of the given target memory cell increases to above the associated verify voltage level V_{V}, then programming may be complete for the given target memory cell. As described in further detail below, a sense block 146 may participate in a program-verify operation that determines whether programming for a given memory cell is complete.

As previously mentioned, target memory cells subject to a program operation may also be subject to a verify operation that determines when programming is complete for each of the target memory cells. The verify operation is done in between program pulses, and so the programming operation and the verify operation in performed in an alternating or looped manner. The combination of the programming operation and the verify operation is called a program-verify operation. Accordingly, a program-verify operation includes a plurality of programming operations and a plurality of verify operations that are alternatingly performed. That is, a program-verify operation involves a programming operation followed by a verify operation, followed by another programming operation, followed by another verify operation, and so on until the program-verify operation has no more programming or verify operations to be performed. In addition, a single programming operation of a program-verify operation includes the power control circuitry 160 supplying one or more program pulses to the selected word line for that single programming operation, and a single verify operation of a program-verify operation includes the power control circuitry 160 supplying one or more verify pulses to the selected word line for that single programming operation. Accordingly, a program-verify operation may include the power control circuitry 160 supplying a pulse train or a series of voltage pulses to the selected word line, where the pulse train includes one or more program pulses followed by one or more verify pulses, followed by one or more program pulses, followed by one or more verify pulses, and so on until the program-verify process has no more program or verify pulses for the power control circuitry 160 supply to the selected word line.

A program-verify operation is complete when the verify portion of the program-verify operation identifies that all of the memory cells have been programmed to their assigned threshold voltages V_{TH}. As mentioned, the verify process verifies or determines that a given target memory cell is finished being programmed when the verify process determines that the target memory cell's threshold voltage has increased to above the verify voltage level Vv associated with the memory state to which the target cell is to be programmed.

For some example program-verify operations, all of the target memory cells subject to a program-verify operation are not subject to a single verify operation at the same time. Alternatively, for a single verify operation, only those target memory cells that are assigned to the same memory state are subject to a verify operation. For a single verify operation, target memory cells that are subject to the single verify operation are called selected memory cells or selected target memory cells, and target memory cells that are not subject to the single verify operation are called unselected memory cells or unselected target memory cells. Likewise, for a group of bit lines connected to the target memory cells of a program-verify operation, bit lines connected to the selected memory cells for a single verify operation are called selected bit lines, and bit lines connected to the unselected memory cells for a single verify operation are called unselected bit lines. In this context, a state of the bit line may refer to whether the bit line is selected or unselected. Otherwise stated, a bit line can be in one of two states, selected or unselected.

For each of the verify operations, the power control circuitry 160, or some combination of the power control circuitry 160, the read/write circuitry 144, and the sense blocks 146, may supply voltages at appropriate levels to the selected and unselected word lines and the selected and unselected bit lines in order for a verify operation to be performed for the selected memory cells of the target memory cells subject to the program-verify operation. For clarity, and unless otherwise specified, the combination of the power control circuitry 160, the read/write circuitry 144, and the sense blocks 146 used to bias the selected and unselected word lines and bit lines at appropriate levels during a given memory operation (e.g., a programming operation, a verify operation, a program-verify operation, a read operation, or an erase operation) is herein referred to collectively as voltage supply circuitry. Voltage supply circuitry may refer to the power control circuitry 160, the sense block circuitry 146, other circuit components of the read/write circuitry 144, or any combination thereof.

For performance of a verify operation in a block, the voltage supply circuitry may supply a drain select gate bias voltage V_{SGD} on the drain select gate bias line SGD to the control gates of the drain select gate transistors (e.g., transistors 606 of FIG. 6) and a source select gate bias voltage V_{SGS} on the source select gate bias line SGS to the control gates of the drain select gate transistors (e.g., transistors 608 of FIG. 6) at levels that turn on the drain select gate transistors and the source select gate transistors in response to the voltage supply circuitry supplying voltages at suitable levels on the common source line SL and to the bit lines.

Additionally, the voltage supply circuitry supplies a source line voltage at a cell source voltage level Vcelsrc, otherwise referred to as the cell source voltage Vcelsrc, on the common source line SL. Further, the voltage supply circuitry biases the drain side of the selected bit lines with a high supply voltage VHSA that is higher in magnitude than the cell source voltage Vcelsrc. The difference between the high supply voltage VHSA and the cell source voltage level Vcelsrc may be great enough to allow current to flow from the drain side to the source side of a string that includes a selected target memory cell in the event that the selected target memory cell has a threshold voltage V_{TH} that allows it to conduct a current. During a verify operation, a selected memory cell can be generally characterized as fully conducting, marginally conducting, or non-conducting, depending on the threshold voltage V_{TH} of the selected memory cell. Also, the voltage supply circuitry biases the drain side of the unselected bit lines to the cell source voltage Vcelsrc. By biasing the drain side and the source side of unselected bit lines to the cell source voltage Vcelsrc, the voltage difference between the drain side and source side voltages will not allow current to flow through the NAND string connected to the unselected bit line. Further, the voltage supply circuitry biases the unselected word lines, and in turn the control gates of FGTs coupled to the unselected word lines, to a read voltage Vread. The read voltage is high enough to cause the FGTs coupled to unselected word lines to conduct a current regardless of its threshold voltage V_{TH}. In addition, the voltage supply circuitry biases the selected word line with a control gate reference voltage V_{CGRV}, which may be in the form of one or more verify pulses as previously described. The control gate reference voltage V_{CGRV} may be different for verification of target memory cells of different memory states. For example, the voltage supply circuitry may supply a different control gate reference voltage V_{CGRV} (or a control gate reference voltage V_{CGRV} at different level) when verifying target memory cells programmed to state A than when verifying target memory cells programmed to state B, and so on.

Once the voltage supply circuitry supplies the voltages to the selected and unselected word lines and bit lines, and to the drain select gate transistors, source select gate transistors, drain select gate bias line SGD, and source select gate bias line SGS, a sense block can perform a sense operation that identifies whether a selected target memory cell is conducting, and in turn sufficiently programmed. Further details of the sense operation portion of the verify operation are described in further detail below.

As previously described, the threshold voltage V_{TH} of a memory cell may identify the data value of the data it is storing. For a given read operation in a block, a memory cell from which data is to be read is referred to as a selected memory cell, and a memory cell from which data is not to be read is referred to as an unselected memory cell. So, when data is to be read from a page of memory cells for a particular read operation, those memory cells in the page are the selected memory cells, and the memory cells of the block that are not part of the page are the unselected memory cells. Additionally, a word line connected to the page of selected memory cells is referred to as the selected word line, and the other word lines of the block are referred to as the unselected word lines.

During a read operation to read data stored in target memory cells of a page, the sense blocks 146 may be configured to perform a sense operation that senses whether current is flowing through the bit lines connected to the target memory cells of the page. The voltage supply circuitry may supply voltages on the selected and unselected word lines at appropriate levels that cause current to flow or not to flow based on the threshold voltage V_{TH} of the target memory cells. For some configurations, the level of the voltage supplied to the selected word lines may vary depending on the states of the memory cells.

The voltage supply circuitry may also bias the bit lines so that the high supply voltage VHSA is applied to the drain side of the bit lines and the cell source voltage Vcelsrc is applied to the source side of the bit lines to allow for the current flow, provided that the threshold voltage V_{TH} of the selected memory cell allows for it. For some example read configurations, where the sense block 146 can perform a sense operation for fewer than all of the memory cells of a page. For such configurations, the target memory cells of the page that are subject to and/or that are selected for a given sense operation are referred to as selected memory cells or selected target memory cells. Conversely, the target memory cells of the page that are not subject to and/or that are not selected for the sense operation are referred to as unselected memory cells. Accordingly, bit lines connected to selected target memory cells are referred to as selected bit lines, and bit lines connected to unselected target memory cells are referred to as unselected bit lines. In this context, a state of the bit line may refer to whether the bit line is selected or unselected. Otherwise stated, a bit line can be in one of two states, selected or unselected. The voltage supply circuitry can supply the voltages to the selected and unselected word lines and the selected and unselected bit lines at levels in various combinations and/or in various sequences and/or over various sense operations in order determine the threshold voltages of the target memory cells so that the data values of the data that the target memory cells are storing can be determined.

For some example configurations, word lines among a plurality blocks, including those located in different planes, may be grouped into sets of shared word lines. In a particular example configuration, word lines in the same shared set are located in different blocks and different planes from each other. In addition, word lines are part of the same shared set if they are configured to be connected to the same voltage generator and configured to simultaneously receive the same voltage from the same voltage generator. So, when a voltage generator generates a voltage, that voltage is supplied to those word lines that are part of the same shared set of word lines. For some example configurations, word line switching circuitry disposed in between the voltage generator may enable word lines of the same shared set to be selectably coupled to the voltage generator. Accordingly, depending on the configuration of the word line switching circuitry, the voltage generator may supply its voltage to all of the word lines of the same shared set, or less than all of the word lines of the same shared set.

The peripheral circuitry 152 and/or the read/write circuits 144 of a memory die 104 (FIG. 2B) may be configured to concurrently perform memory operations (e.g., read operations, program operations, or verify operations) on memory cells that are connected to different word lines of the same shared set. One way that they can do so is by having a voltage generator concurrently supply a selected word line voltage V_{SWL} to word lines of the same shared set. To illustrate, suppose a first word line of a shared set is the selected word line for a first associated memory operation and a second word line of the shared set is the selected word line for a second memory operation. A voltage generator included in the peripheral circuitry 152 (e.g., in the power control circuitry 160), and/or in the read/write circuitry 144 may concurrently supply a selected word line voltage V_{SWL} (or a voltage at a selected word line level) to the first selected word line and to the second selected word line for concurrent or simultaneous performance of the first and second memory operations.

During performance of concurrent memory operations, in the event that a first word line a shared set has a defect related to a short between it and a physically adjacent or neighboring word line, leakage current that flows as a result of the short may cause an offset voltage to occur on the first word line and, in turn, the voltage supply line or path that is delivering the selected word line voltage V_{SWL} from the voltage generator to the first word line. Consequently, that offset voltage may contribute to the level of the voltage that is supplied one or more other word lines of the shared set, even if those other word lines are not themselves defective. The memory operation(s) being concurrently performed for those other word lines of the shared set may fail due to the defect of the first word line and the offset voltage on the supply line that the defect created.

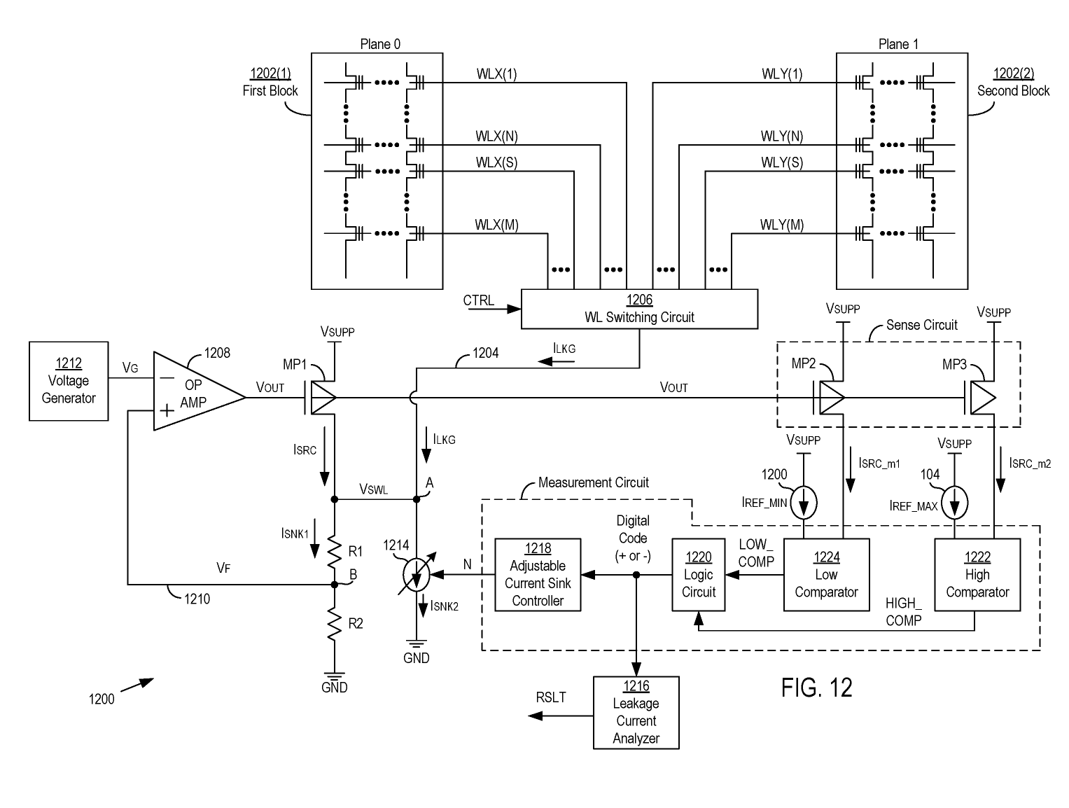

FIG. 12 shows a schematic diagram of an example leakage current detection circuit 1200 that is configured to sense, detect, and measure leakage current from the array of memory cells 142 (FIG. 2B). The leakage current detection circuit 1200 may be located on the memory die 104 and be a component of the peripheral circuitry 152, a component of the read/write circuits 144, or a separate component on the memory die 104. Additionally, a memory die 104 may include a single leakage current detection circuit 1200 or a plurality of leakage detection circuits 1200. For example, the number of leakage detection circuits may correspond to the arrangement or shared word lines in the array. In particular, a leakage current detection circuit 1200 may be connected to blocks that have word lines that are part of the same sets of shared word lines.

In the example configuration shown in FIG. 12, the leakage current detection circuit 1200 is connected to two blocks, including a first block 1202(1) and a second block 1202(2) located in different planes. The first block 1202(1) is located in a first plane (Plane 0) and the second block 1202(2) is located in a second plane (Plane 1). Each of the blocks 1202(1), 1202(2) may include an M-number of word lines. In particular, the first block 1202(1) includes a first word line WLX(1) extending to an Mth word line WLX(M), and the second block 1202(2) includes a first word line WLY(1) extending to an Mth word line WLY(M). Each word line WLX in the first block 1202(1) may be part of a set of shared word lines with a word line WLY in the second block 1202(2).

In addition, for purposes of illustration, one of the word lines WLX of the first block 1202(1) is a selected word line WLX(S) of the word lines WLX, and one of the word lines WLY of the second block 1202(2) is a selected word line WLY(S) of the word lines WLY. The selected word line WLX(S) of the first block 1202(1) and the selected word line WLY(S) of the second block 1202(2) may be part of or form the same set of shared word lines. Other word lines WLX, WLY may similarly be part of or form other sets of shared word lines. For clarity, the selected word line WLX(S) of the first block 1202(1) is referred to as the first selected word line WLX(S), and the selected word line WLY(S) of the second block 1202(2) is referred to as the second selected word line WLX(Y).

Also, for purposes of illustration, one of the word lines WLX of the first block 1202(1) is a neighboring word line WLX(N) of the first selected word line WLX(S), and one of the word lines WLY of the second block 1202(2) is a neighboring word line WLY(N) of the second selected word line WLY(S). A neighboring word line of a reference word line is a word line that is physically adjacent to the reference, or a predetermined number of word lines away from the reference word line. Additionally, as used herein, a neighboring word line of a reference word line is a word line that may form a short with the reference word line to cause leakage current to flow through the reference word line. FIG. 12 shows the neighboring word lines WLX(N), WLY(N) as being neighbors of the selected word lines WLX(S), WLY(S). Although not shown, the selected word lines WLX(S), WLY(S) may have other or additional neighboring word lines.

In general, at a given point in time, any of the M-number of word lines WLX(1) to WLX(M) can be a selected word line WLX(S), and any of the M-number of word lines WLY(1) to WLY(M) can be a selected word line WLY, depending on the memory operation and/or which word line is to be selected for performance of a memory operation. Additionally, each of the M-number of word lines WLX, WLY in the first and second blocks 1202(1), 1202(2) can be or qualify as neighboring word lines of physically adjacent or certain other word lines in their respective blocks 1202(1), 1202(2).

The leakage current detection circuit 1200 may be selectably connected to the word lines WLX of the first block 1202(1) and to the word lines WLY of the second block via a voltage supply line or path 1204 and word line (WL) switching circuit 1206. The leakage current detection circuit 1200 may be configured to generate a selected word line voltage V_{SWL} according to one or more memory operations (e.g., a read, program, or verify operation) at a node A that is connected to the voltage supply line 1204, and supply the selected word line voltage V_{SWL} via the voltage supply line 1204 to the WL switching circuit 1206. In response, the WL switching circuit 1206 may supply the selected word line voltage V_{SWL} to either the first word selected word line WLX(S), the selected word line WLY(S), or both. As shown in FIG. 12, the WL switching circuit 1206 may receive a control signal CTRL that controls the state of the WL switching circuit 1206 in order to have the WL switching circuit 1206 supply selected word line voltage V_{SWL} to the first word selected word line WLX(S), the selected word line WLY(S), or both. The control logic 154 or the read/write circuit 144 controlling a given memory operation may be configured to generate and output the control signal CTRL.

The leakage current detection circuit 1200 may include a voltage regulation or generation circuit that is configured to generate and regulate, at node A, the selected word line voltage V_{SWL} that is supplied to one or both of the selected word lines WLX(S), WLY(S). The voltage regulation circuit may regulate the selected word line voltage V_{SWL} by supplying a source current I_{SRC} to node A and adjusting the level or amount of the source current I_{SRC} to maintain the selected word line voltage V_{SWL} at a target level. The target level may be a predetermined selected word line level for a particular memory operation, such as a selected word line level for a read operation, a program operation, or a verify operation, as previously described.

In further detail, the voltage regulation circuit may include an operational amplifier (op amp) 1208, a first p-channel metal-oxide-semiconductor field-effect transistor (PMOS transistor) MP1, a resistor divider network, including a first resistor R1 and a second resistor R2, and a feedback connection 1210. The first PMOS transistor MP1 may include a source terminal configured to receive a supply voltage V_{SUPP}, a drain terminal connected to node A, and a gate terminal connected to an output of the op amp 1208. The first resistor R1 may include a first end connected to node A and a second end connected to node B. The second resistor R2 may include a first end connected to node B and a second end connected to ground (GND). The resistor divider network may be configured to generate a feedback voltage V_{F} at node B based on the selected word line voltage V_{SWL} and the resistance values of the first and second resistors R1, R2. The op amp 1208 may include a first (negative) input terminal that is configured to receive a generator voltage V_{G} from a voltage generator 1212, which may be a component of the power control circuitry 160 or the read/write circuits 144 (FIG. 2B). In addition, the op amp 1208 may include a second (positive) input terminal that is configured to receive the feedback voltage V_{F} via the feedback connection 1210, which has a first end connected to the second input terminal and a second end connected to node B. The op amp 1208 may further include an output that is configured to output an output voltage V_{OUT} based on and/or indicative of the difference between the level of the generator voltage V_{G} and the level of the feedback voltage V_{F}. The op amp 1208 may supply its output voltage V_{OUT} to the gate terminal of the first PMOS transistor MP1. In response to the output voltage V_{OUT}, the first PMOS transistor MP1 may generate the source current ISRC and supply or source the source current I_{SRC} to node A. The amount or level of the source current ISRC may depend on the amount or level of the output voltage V_{OUT}.

The voltage regulation circuit uses the generator voltage V_{G} received from the voltage generator 1212 to generate the source current I_{SRC} and in turn the selected word line voltage V_{SWL}. The voltage regulation circuit monitors and regulates the selected word line voltage V_{SWL} to the target level, which may be predetermined selected word line level for a particular memory operation, such as a selected word line level for a read operation, a program operation, or a verify operation, as previously described. The voltage regulation circuit may regulate the selected word line voltage V_{SWL} by supplying a first sink current I_{SNK1} from node A through the first resistor R1 to node B to generate the feedback voltage V_{F}. As long as the level of the selected word line voltage V_{SEL} remains constant, the amount of the first sink current I_{SNK1} will remain constant, which in turn causes the feedback voltage V_{F} to remain constant, which in turn causes the level of the output voltage V_{OUT} to remain constant, which in turn causes the source current ISRC to remain constant. However, if the level of the selected word line voltage V_{SWL} begins to vary (increase or decrease), that variation causes a corresponding change in the amount of the first sink current I_{SNK1}, in turn the level of the feedback voltage V_{F}, in turn the level of output voltage V_{OUT}, which causes an adjustment in the amount of the source current _{SRC} to bring back the level of the selected word line voltage V_{SWL} to the target level.

During concurrent memory operations for memory cells connected to the selected word lines WLX(S), WLY(S), the selected word line voltage V_{SWL} generated at node A may be supplied to the selected word lines WLX(S), WLY(S) via the voltage supply path 1204 and the WL switching circuit 1206. While the selected word line voltage V_{SWL} is being applied to the selected word lines WLX(S), WLY(S), in the event that one or both of the selected word lines WLX(S), WLY(S) is defective due to a short with its associated neighboring word line WLX(N), WLY(N), a leakage current I_{LKG} caused by the defect may flow to node A from the defective word line(s) WLX(S), WLY(S) to node A via the WL switching circuit 1206 and the voltage supply path 1204. In this way, the leakage current I_{LKG} functions as a second source current to node A.

In the event that leakage current I_{LKG} is sourced to node A, the voltage regulation circuit may be configured to adjust the level of the source current I_{SRC} in response to the leakage current I_{LKG} in order to regulate the selected word line voltage V_{SWL} to the target level. For example, while the selected word line voltage V_{SWL} is being generated at node A, should the leakage current I_{LKG} be present, the leakage current I_{LKG} sourced to node A will cause the level of the selected word line voltage V_{SWL} to increase by an amount proportional to the amount of the leakage current I_{LKG}. The voltage regulation circuit will monitor this increase in the level of the selected word line voltage V_{SWL} and respond by decreasing the level of the source current I_{SRC} in order bring back the level of the selected word line voltage V_{SWL} to the target level. In general, the voltage regulation circuit decreases the source current I_{SRC} corresponding to the extra leakage current I_{LKG} in order to maintain the selected word line voltage V_{SWL} at a constant, target level. The amount that the source current I_{SRC} decreases is proportional to and/or equal to the amount of the leakage current I_{LKG}.

During the concurrent memory operations while the selected word line voltage V_{SWL} is being applied to the selected word lines WLX(S), WLY(S), in the event that leakage current I_{LKG} is present, the leakage current detection circuit 1200 may include a sense circuit that is configured to sense the presence of the leakage current I_{LKG} and the amount of the leakage current I_{LKG}. The sense circuit may be configured to sense the presence of the leakage current by sensing a change in the level of the source current I_{SRC}. Likewise, the sense circuit may be configured to sense the amount of the leakage current by sensing an amount that level of the source current I_{SRC} has changed, since the change in the level and the amount of the change corresponds to and/or is equal to the amount of the leakage current I_{LKG}. The sense circuit may further be configured to generate at least one sense current in response to its sensing. The at least one sense current is indicative of the level of the source current I_{SRC} and any adjustment in the level of the source current I_{SRC}.

The leakage current detection circuit 1200 may further include a measurement circuit that is configured to measure the amount of the leakage current I_{LKG} sourced to node A during supply of the selected word line voltage V_{SWL}. The measurement circuit may be configured measure the amount of the leakage current I_{LKG} in response to the sensing performed by the sense circuit and the one or more sense currents that the sense circuit generates in response to its sensing. In addition, for some example configurations, the measurement circuit may be configured to measure the amount by quantifying the amount and representing the quantified current amount by a digital value or code, such as an n-bit binary value for example.

The measurement circuit may include or be connected to an adjustable current sink 1214. The measurement circuit may be configured to control the adjustable current sink 1214 to sink, from node A, an amount of current corresponding to the amount of the leakage current I_{LKG} that it measures. To sink current from node A, the adjustable current that is configured to generate a second sink current I_{SNK2}. As part of or in conjunction with measuring the amount of the leakage current I_{LKG}, the measurement circuit may set the level of the second sink current I_{SNK2} to the level of the leakage current I_{LKG} that it measures. In the event that the measurement circuit adjusts its measurement, the measurement circuit may respond by adjusting the amount of the second sink current I_{SNK2}. Eventually, the measurement circuit will identify or measure a correct or final amount of the leakage current I_{LKG}, such that the amount or level of the second sink current I_{SNK2} being sunk away from node A will equal the final amount or level of the leakage current I_{LKG} sourced to node A.

By having set the amount or level of the second sink current I_{SNK2}, the measurement circuit will know the final level of the leakage current I_{LKG}, and can provide that final level to a leakage current analyzer circuit 1216, which may be a component of the leakage current detection circuit 1200, another component of the memory die 104, or a component of the controller 102 (FIG. 2A).

The leakage current analyzer 1216 may be configured to compare the final level of the leakage current I_{LKG} with a threshold level. The leakage current analyzer 1216 may further be configured to output a result signal RSLT indicative of the comparison, namely whether the final level of the leakage current I_{LKG} has exceeded the threshold level. The leakage current analyzer 1216 may output the result signal RSLT to control logic 154 and/or the read/write circuit 144 for further processing or decision-making, as described in further detail below.

In further detail, the sense circuit may include a current mirror circuit that forms a current mirror connection with the first PMOS transistor MP1, and that is configured to mirror the source current I_{SRC} to generate a first mirrored source current I_{SRC}_{_}ₘ₁ and a second mirrored source current I_{SRC}_{_}ₘ₂. In the example configuration shown in FIG. 12, the current mirror circuit includes a second PMOS transistor MP2 that is configured to mirror the source current I_{SRC} to generate the first mirrored source current I_{SRC}_{_}ₘ₁, and a third PMOS transistor MP3 that is configured to mirror the source current I_{SRC} to generate the second mirrored source current I_{SRC}_{_}ₘ₂. Since a change in the source current I_{SRC} from an initial level indicates the presence of the leakage current I_{LKG} and the amount of the change in the source current I_{SRC} indicates an amount of the leakage current I_{LKG}, then the current mirror circuit may sense the leakage current I_{LKG} by mirroring the source current I_{SRC} to generate the mirrored source currents I_{SRC}_{_}ₘ₁, ISRC m2 at levels that reflect the change in the source current I_{SRC}. The change in the levels of the mirrored source current I_{SRC}_{_}ₘ₁, I_{SRC}_{_}ₘ₂ from initial levels indicate the presence of the leakage current I_{LKG}, and the amounts that the mirrored source currents I_{SRC}_{_}ₘ₁, I_{SRC}_{_}ₘ₂ have changed indicate the amount of the leakage current.

The measurement circuit may include an adjustable current sink controller 1218, a logic circuit 1220, and a comparison circuit that includes a high comparator circuit 1222 and a low comparator circuit 1224. The adjustable current sink controller 1218 may be configured to generate and output a control signal N to the adjustable current sink 1214. The level or value of the control signal N may set the level or amount of second sink current I_{SNK2} that the adjustable current sink 1214 generates. Accordingly, changes in the level or value of the control signal N may cause the adjustable current sink 1214 to correspondingly change or adjust the level at which the adjustable current sink 1214 generates the second sink current I_{SNK2}.

The comparison circuit may be configured to identify a level of the source current ISRC relative to a high reference current level T_{REF MAX} and a low reference current level I_{REF}_{_}_{MIN}, and output one or more comparison result signals to indicate where the level of the source current I_{SRC} relative to the high and low reference current levels I_{REF}_{_}_{MAX}, I_{REF}_{_}_{MIN}. In the example configuration shown in FIG. 12, the comparison circuit may include the high comparison circuit 1222 and the low comparison circuit 1224 to perform two separate comparisons in order to identify the level of the source current I_{SRC} relative to the high and low reference current levels I_{REF}_{_}_{MAX}, I_{REF}_{_}_{MIN}. In this regard, the current mirror circuit may include two PMOS transistors MP2, MP3, to generate and source two mirrored currents I_{SRC}_{_}ₘ₁, I_{SRC}_{_}ₘ₂ for the two comparisons. In the particular example configuration shown in FIG. 12, the second PMOS transistor MP2 is configured to supply or source the first mirrored source current I_{SRC}_{_}ₘ₁ to the low comparator 1224, and the third PMOS transistor MP3 is configured to supply or source the second mirrored source current I_{SRC}_{_}ₘ₂ to the high comparator 1222.

Upon receipt of the first mirrored source current I_{SRC}_{_}ₘ₁, the low comparator 1224 may be configured to compare the level of the first mirrored source current I_{SRC}_{_}ₘ₁ with the low reference current level I_{REF}_{_}_{MIN}. In the example configuration shown in FIG. 12, a low reference current source 1226 may be configured to supply or source the low reference current I_{REF MIN} (i.e., a reference current at the low reference current level) to the low comparator 1224 in order for the low comparator 1224 to perform its comparison. In response to the comparison, the low comparator 1224 may be configured to output a low comparison result signal LOW_COMP to the logic circuit 1220 at a level that indicates whether the level of the first mirrored source current I_{SRC}_{_}ₘ₁ is above or below (or alternatively has moved to below or has moved to above) the low reference current level I_{REF}_{_}_{MIN}.

Similarly, upon receipt of the second mirrored source current I_{SRC}_{_}ₘ₂, the high comparator 1222 may be configured to compare the level of the second mirrored source current I_{SRC}_{_}ₘ₂ with the high reference current level I_{REF}_{_}_{MAX}. In the example configuration shown in FIG. 12, a high reference current source 1228 may be configured to supply or source the high reference current I_{REF}_{_}_{MAX} (i.e., a reference current at the high reference current level) to the high comparator 1222 in order for the high comparator 1222 to perform its comparison. In response to the comparison, the high comparator 1222 may be configured to output a high comparison result signal HIGH_COMP to the logic circuit 1220 at a level that indicates whether the level of the second mirrored source current I_{SRC}_{_}ₘ₂ is above or below (or alternatively has moved to below or has moved to above) the high reference current level I_{REF MAX}.

The logic circuit 1220 may be configured to measure the amount of the leakage current. In particular, the logic circuit 1220 may measure the amount of the leakage current by controlling the adjustable current sink 1214 to keep or maintain the source current I_{SRC} in a target current range, and determining or keeping track of how much the adjustable current sink 1214 adjusted the level of the second sink current I_{SNK2} in order to keep the source current I_{SRC} in the target current range. The logic circuit 1220 may determine if the level of the second sink current I_{SNK2} is to be adjusted by analyzing the high and low comparison result signals HIGH_COMP, LOW_COMP.

The logic circuit 1220 may be configured to determine a level at which the adjustable current sink 1214 is to generate the second sink current I_{SNK2}, and instruct the adjustable current sink controller 1218 to have the adjustable current sink 1214 generate the second sink current I_{SNK2} at the determined level. The logic circuit 1220 may instruct the adjustable current sink controller 1218 by outputting a digital code having a value that indicates the level at which the second sink current I_{SNK2} is to be generated. If the logic circuit 1220 determines that the second sink current I_{SNK2} is to be changed, the logic circuit 1220 may correspondingly change the value of the digital code to indicate the new level for the second sink current I_{SNK2} and/or the amount by which the second sink current I_{SNK2} is to be changed.

Additionally, the logic circuit 1220 may be configured to measure the amount of the leakage current by keeping track of the changes in the level of the second sink current I_{SNK2}. In particular, the logic circuit 1220 may keep track of a quantified current amount for the leakage current. At the start of a leakage current detection process, the logic circuit 1220 may set the quantified current amount to an initial or default value, which may be zero. In other words, the logic circuit 1220 starts out by assuming that the leakage current is zero. Subsequently, if the logic circuit 1220 determines to adjust the second sink current I_{SNK2} by an amount to keep the source current I_{SRC} in the target current range, the logic circuit 1220 may correspondingly adjust the quantified current amount by the amount it determined to adjust the second sink current I_{SNK2}. In this regard, the value of the digital code that the logic circuit 1220 outputs at a given moment in time indicates the amount of the leakage current that the logic circuit 1220 has measured at that given moment in time. At the end of the leakage current detection process, the final value of the digital code may indicate the amount of the quantified current that the logic circuit 1220 has determined to be the amount of the leakage current.

For some example configurations, the logic circuit 1220 may be configured to have the adjustable current sink 1214 adjust the second sink current I_{SNK2} by incrementing and decrementing the level of the second sink current I_{SNK2} in discrete steps according to a step size. When the logic circuit 1220 determines to increase the second sink current I_{SNK2}, the logic circuit 1220 may determine to increment or step-up the amount of the second sink current I_{SNK2} by the step size. Similarly, when the logic circuit 1220 determines to decrease the second sink current I_{SNK2}, the logic circuit 1220 may determine to decrement or step-down the amount of the second sink current I_{SNK2} by the step size. In this context, by adjusting the level of the second sink current I_{SNk} in step sizes or discrete amounts, the adjustable current sink 1214 may be a quantization current sink.

When adjusting the second sink current I_{SNK2} in discrete steps, the logic circuit 1220 may correspondingly keep track and update the quantified current amount for the leakage current I_{LKG} in discrete steps. For example, when the logic circuit 1220 has the adjustable current sink 1214 increment the second sink current I_{SNK2} by a step size, the logic circuit may correspondingly increment the quantified current amount by the step size. Likewise, when the logic circuit 1220 has the adjustable current sink 1214 decrement the second sink current I_{SNK2} by a step size, the logic circuit may correspondingly decrement the quantified current amount by the step size.

In addition, the logic circuit 1220 may be configured to instruct the adjustable current sink controller 1218 to set the level at which the adjustable current sink 1214 generates the second sink current I_{SNK2} by outputting a digital code having a value that indicates the level. If the logic circuit 1220 determines that the level of the second sink current I_{SNK2} is to be adjusted, the logic circuit 1220 may change a current value of the digital code to a new value that indicate the level to which the second sink current is to be adjusted.

For some example configurations, the adjustable current source 1214 and the adjustable current source controller 1218 may form or be implemented as a digital-to-analog converter (DAC). The digital code output by the logic circuit 1220 may be the input to the DAC, and the output of the DAC may be the second current sink I_{SNK2} output with the adjustable current source 1214.

In further detail of the leakage current measurement, at the start of a leakage current detection process, the logic circuit 1220 may be configured to start from the assumption that there is no leakage current I_{LKG} and initially set the quantified current amount for the leakage current I_{LKG} to zero. Subsequently, as the leakage current detection process proceeds, based on the high comparison result signal HIGH_COMP and the low comparison result signal LOW_COMP, if there is leakage current I_{LKG} as reflected in changes in the first and second mirrored source currents I_{SRC}_{_}ₘ₁, I_{SRC}_{_}ₘ₂, the logic circuit 1220 may be configured to increment (step up) and decrement (step down) the quantified current amount in discrete current steps or discrete increments and decrements. A step size, which is a single amount by which the logic circuit 1220 can increment or decrement the quantified current amount, may be in units of current suitable for measurement of the leakage current I_{LKG}, such as nanoamps (nA) or picoamps (pA) for example. In addition or alternatively, for some example configurations, a step size may be equal to the difference between the high reference current level I_{REF}_{_}MAX and the low reference current level I_{REF}_{_}_{MIN}.

Additionally, in order to quantify the amount of the leakage current I_{LKG}, the voltage regulation circuit may be configured to generate the source current Ism at an initial level, and in turn the current mirror circuit may be configured to generate the first and second mirrored source currents I_{SRC}_{_}ₘ₁, I_{SRC}_{_}ₘ₂ at initial levels such that if there is no leakage current I_{LKG}, the source current levels are in between the high reference current level I_{REF}_{_}_{MAX} and the low reference current level I_{REF}_{_}_{MIN}. In turn, the low comparator 1224 may output its low comparison result signal LOW_COMP at a level (e.g., a low level) to indicate that the first mirrored source current I_{SRC}_{_}ₘ₁ is above the low reference current level I_{REF}_{_}_{MIN}, and the high comparator 1222 may output is high comparison result signal HIGH_COMP at a level (e.g., a low level) to indicate that the second mirrored source current I_{SRC}_{_}ₘ₂ is below the high reference current level I_{REF}_{_}_{MAX}. This may indicate to the logic circuit 1220 that there is no leakage current I_{LKG} (or at least if there is leakage current I_{LKG}, it is not at a detectable, measurable, or quantifiable amount).

The logic circuit 1220 may be configured to generate a digital code at a value that indicates a quantified amount of the leakage current I_{LKG}. At the initial time that the leakage current detection process begins, the logic circuit 1220 may determine that there is no leakage current I_{LKG}, and so may output the digital code at a value to indicate that there is no leakage current I_{LKG}. The logic circuit 1220 may output the digital code to the adjustable current sink controller 1218. In response, the adjustable current sink controller 1218 may generate the control signal N at a level that causes the adjustable current sink 1214 to generate no current (i.e., to generate the second sink current I_{SNK2} at zero amps).

In the event that leakage current I_{LKG} is present on the voltage supply line 1204 and sourced to node A, the logic circuit 1220 may determine the amount of the leakage current I_{LKG} by adjusting the quantified current amount, and correspondingly the value of the digital code representing the quantified current amount, in order to maintain the source current I_{SRC}, and in turn the first and second mirrored source currents I_{SRC}_{_}ₘ₁, I_{SRC}_{_}ₘ₂, at a level in between the high reference current level I_{REF}_{_}_{MAX} and the low reference current level I_{REF}_{_}_{MIN}. In this regard, the high reference current level I_{REF}_{_}_{MAX} and the low reference current level I_{REF}_{_}_{MIN} may define a target current range, where the target current range is a range of current values extending from the high reference current level I_{REF}_{_}_{MAX} to the low reference current level I_{REF}_{_}_{MIN}. A current level that is higher than the high reference current level I_{REF MAX} or lower than the low reference current level I_{REF MIN} may be considered outside of the target current range. In the event that leakage current I_{LKG} is present, the logic circuit 1220 be configured to increase and decrease the quantified current amount, and correspondingly the values of the digital code it outputs, in order to adjust the amount of the second sink current I_{SNK2} to maintain or regulate the source current I_{SRC} to within the target current range. In doing so, the logic circuit may quantify the amount of the leakage current I_{LKG}.

In further detail, increasing the value of the digital code may cause the source current I_{SRC}, and in turn the first and second mirrored source currents I_{SRC m1}, I_{SRC m2}, to decrease. That is, when the logic circuit 1220 increases or increments the value of the digital code by an amount corresponding to a current step size, the adjustable current sink controller 1218 may respond by increasing the level of the control signal N by an amount that, in turn, causes the adjustable current sink 1214 to increase the second sink current I_{SNK2} by the current step size. Sinking more current away from node A may cause the voltage regulation circuit to correspondingly increase the source current I_{SRC} it sources to node A in order to regulate the selected word line voltage V_{SWL} to the target level. Conversely, when the logic circuit 1220 decreases or decrements the value of the digital code by an amounted corresponding to a current step size, the adjustable current sink controller 1218 may respond by decreasing the level of the control signal N by an amount that, in turn, causes the adjustable current sink 1214 to decrease the second sink current I_{SNK2} by the step size. Sinking less current away from node A may cause the voltage regulation circuit to correspondingly decrease the source current I_{SRC} it sources to node A in order to regulate the selected word line voltage V_{SWL} at the target level.

The logic circuit 1220 may determine whether to increase or decrease the quantified current amount in response to the level of the source current I_{SRC}, and in turn the levels of the first and second mirrored source currents I_{SRC m1}, I_{SRC m2}, crossing (i.e., moving from above to below or from below to above) the low and high reference current levels I_{REF}_{_}_{MIN}, I_{REF}_{_}_{MAX}, as indicated by the low comparison result and high comparison result signals LOW_COMP, HIGH_COMP. In particular, each time the source current I_{SRC} moves from above the low reference current level I_{REF}_{_}_{MIN} to below the low reference current level I_{REF}_{_}_{MIN}, the low comparator 1224 may output its low comparison result signal LOW_COMP to indicate this occurrence. In response, the logic circuit 1220 may increase the quantified current amount by one step size and correspondingly adjust the value of the digital code to indicate the increase. In addition, each time the source current I_{SRC} moves from below the high reference current level I_{REF}_{_}_{MAX} to above the high reference current level I_{REF}_{_}_{MAX}, the high comparator 1224 may output its high comparison result signal HIGH_COMP to indicate this occurrence. In response, the logic circuit 1220 may decrease the quantified current amount by one step size and correspondingly adjust the value of the digital code to indicate the decrease.

In further detail, if the amount of the leakage current I_{LKG} causes the first mirrored source current I_{SRC}_{_}ₘ₁ to decrease to below the low reference current level I_{REF}_{_}_{MIN}, the low comparator 1224 may identify this occurrence and output its low comparison output signal LOW_COMP to indicate that the first mirrored current I_{SRC}_{_}ₘ₁ fell below the low reference current level I_{REF}_{_}_{MIN}. In response, the logic circuit 1220 may increase the quantified current amount by a step size, and correspondingly increase the digital code to cause the adjustable current sink controller 1218 to increase the level of the second sink current I_{SNK2} by the step size. Doing so may cause the source current I_{SRC} to increase to back above the low reference current level I_{REF}_{_}_{MIN}. Subsequently, if the leakage current I_{LKG} increases some more, causing the first mirrored source current I_{SRC}_{_}ₘ₁ to again decrease to below the low reference current level I_{REF}_{_}_{MIN}, the logic circuit 1220 may again increase the quantified current amount by a step size, and correspondingly increase the digital code to cause the adjustable current sink controller 1218 to increase the level of the second sink current I_{SNK2}.

In a similar manner, if the amount of the leakage current I_{LKG} causes the second mirrored source current I_{SRC} m2 to increase to above the high reference current level I_{REF}_{_}_{MAX}, the high comparator 1222 may identify this occurrence and output its high comparison output signal HIGH_COMP to indicate that the second mirrored source current I_{SRC}_{_}ₘ₂ rose above the high reference current level I_{REF}_{_}_{MAX}. In response, the logic circuit 1220 may decrease the quantified current amount by a step size, and correspondingly decrease the digital code to cause the adjustable current sink controller 1218 to decrease the level of the second sink current I_{SNK2} by the step size. Doing so may cause the source current I_{SRC} to decrease to back below the low reference current level I_{REF}_{_}_{MIN}. Subsequently, if the leakage current I_{LKG} decreases some more, causing the second mirrored source current I_{SRC}_{_}ₘ₂ to again increase to above the high reference current level I_{REF}_{_}_{MAX}, the logic circuit 1220 may again decrease the quantified current amount by a step size, and correspondingly decrease the digital code to cause the adjustable current sink controller 1218 to decrease the level of the second sink current I_{SNK2}.

The logic circuit 1220 may also be configured to check, upon expiration of predetermined time periods or intervals, if the source current I_{SRC} moved back to within or between the high reference current level I_{REF} and the low reference current level I_{REF}_{_}_{MIN} after incrementing or decrementing the quantified current amount and the amount of the second sink current I_{SNK2} by the step size. For example, after the logic circuit 1220 increments the quantified current amount by the step size, the logic circuit 1220 may start a timer that begins a time period. During the time period, the logic circuit 1220 may monitor if the source current I_{SRC} has risen to above the low reference current level IREF_MIN, as indicated by the low comparison result signal LOW_COMP. If it does before the time period expires, then the logic circuit 1220 may stop the timer. Alternatively, if the source current I_{SRC} does not rise to above the low reference current level I_{REF}_{_}_{MIN}, as indicated by the low comparison result signal LOW_COMP, and the time period expires, the logic circuit 1220 may again increment the quantified current amount by the step size and reset the timer to start another time period. This way, through use of the timer, the logic circuit 1220 can increase the second sink current I_{SNK2}, and in turn increase the source current I_{SRC} to back to above the low reference current level I_{REF}_{_}_{MIN} in the event that an increase in the leakage current I_{LKG} is greater than a step size such that increasing the second sink current I_{SNK2} by one step size does not increase the source current I_{SRC} to back above the low reference current level I_{REF}_{_}_{MIN}.

In a similar manner, after the logic circuit 1220 decrements the quantified current amount by the step size, the logic circuit 1220 may start the timer to begin a time period. During the time period, the logic circuit 1220 may monitor if the source current I_{SRC} falls to below the high reference current level I_{REF}_{_}_{MAX}, as indicated by the high comparison result signal HIGH_COMP. If it does before the time period expires, then the logic circuit 1220 may stop the timer. Alternatively, if the source current I_{SRC} does not fall to below the high reference current level I_{REF MAX}, as indicated by the high comparison result signal HIGH_COMP, and the time period expires, the logic circuit 1220 may again decrement the quantified current amount by the step size and reset the timer to start another time period. This way, through use of the timer, the logic circuit 1220 can decrease the second sink current I_{SNK2}, and in turn decrease the source current I_{SRC} to back to below the high reference current level I_{REF}_{_}_{MAX} in the event that a decrease in the leakage current I_{LKG} is greater than a step size such that decreasing the second sink current I_{SNK2} by one step size does not decrease the source current I_{SRC} to back below the high reference current level I_{REF}_{_}_{MAX}.

After a period of time following the start of the leakage current detection process, the amount or level of the leakage current I_{LKG} may become steady or constant, which in turn will cause the level of the source current I_{SRC}, and the levels of the first and second mirrored source currents I_{SRC}_{_}ₘ₁, I_{SRC}_{_}ₘ₂, to stay within or between the low and high reference current levels I_{REF}_{_}_{MIN}, I_{REF}_{_}_{MAX} without the logic circuit 1220 having to adjust the value of the quantified current amount and the digital code. At this time, the value of the quantified current amount may be a final quantified current amount that represents and/or is equal to the amount of the leakage current I_{LKG}. This final quantified current amount may be indicated by a final value of the digital code that the logic circuit outputs.

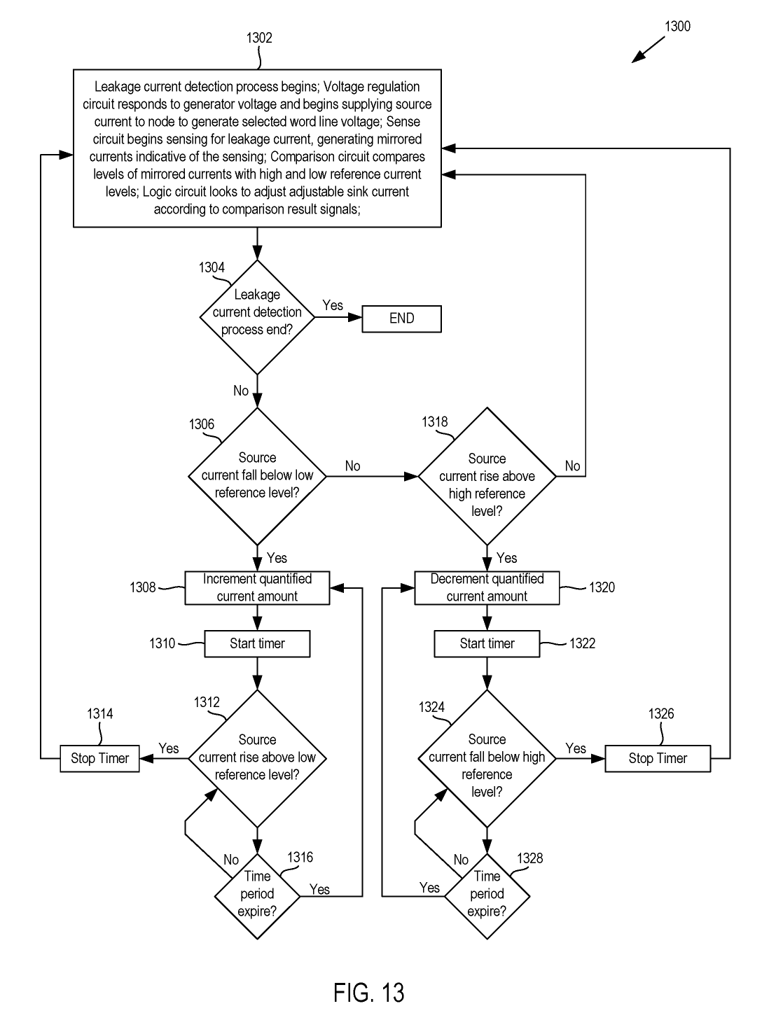

FIG. 13 shows a flow chart of an example method 1300 of performing a leakage current detection process. The method 1300 is described as being performed with the leakage current detection circuit 1200 of FIG. 12, although performance of the method 1200 with other leakage detection circuits may be possible.

At block 1302, the leakage current detection process may begin when the voltage regulation circuit responds to the generator voltage V_{G} received from the voltage generator 1212 and begin supplying the source current I_{SRC} to node A to generated the selected word line voltage V_{SWL}. For some example methods, the leakage current detection process may be run concurrently with a single memory operation or two or more concurrent memory operations (e.g., one or more read, program, or verify operations) for which the selected word line voltage V_{SWL} is being generated. In some example methods, the one or more memory operations may be performed in response to one or more host requests received from a host device to read or write data. In this context, the leakage current detection process may be considered an on-the-fly leakage current detection process, in that it is performed “on-the-fly” concurrently with or in conjunction with execution of one or more host commands to read or write data. It is not performed separately as a stand-alone test that is performed independent of a memory operation performed in response to receipt of a host request. The selected word line voltage V_{SWL} at node A may be supplied to the WL switching circuit 1206 via the voltage supply line 1204, and the WL switching circuit 1206 may route the selected word line voltage V_{SWL} to the first selected word line WLX(S), the second selected word line WLY(S), or both, depending on the state in which the control signal CTRL configured it. In the event that one or both of the selected word lines WLX(S), WLY(S) are defective in such a way as to cause leakage current I_{LKG}, application of the selected word line voltage V_{SWL} may cause the leakage current I_{LKG} to flow as a second source current to node A via the WL switching circuit 1206 and the voltage supply path 1204.

In other examples of the method 1300, the leakage current detection process may be performed separate from or independent of a memory operation. For such methods, the leakage current detection process may be part of a test process during manufacturing or a background process that is not performed in response to any particular memory operation or received host request. For example, the memory system 100 may be configured to perform memory operations (e.g., read, program, verify operations) as foreground operations in response to particular host requests that request data to be read and written. The memory system 100 may also be configured to perform background operations as part of its memory management that is not specific to a received host request. For example, a background process may monitor the health of a block, such as by monitoring the number of program-erase cycles of that block or the number of times the block was accessed for a read operation, as non-limiting examples. In response to the monitoring, the control logic 154 and/or the read/write circuit 144 may determine to perform a leakage current detection process and control the leakage current detection circuit 1200 to perform the leakage current detection process. For such processes, the voltage generated and regulated at node A is not necessarily a selected word line voltage for a particular memory operation, but instead may be a voltage at a predetermined level that is specific to a test process or a background process.

In addition, at block 1302, the sense circuit may begin sensing for any leakage current I_{LKG} by generating the mirrored source currents I_{SRC}_{_}ₘ₁, I_{SRC}_{_}ₘ₂, and the comparison circuit may compare the mirrored source currents I_{SRC}_{_}ₘ₁, I_{SRC}_{_}ₘ₂ with the low and high reference current levels I_{REF}_{_}_{MIN}, I_{REF}_{_}_{MAX}, and output the low and high comparison result signals LOW_COMP, HIGH_COMP to the logic circuit 1220, indicating whether the source current I_{SRC} is within the target current range or has moved to outside the target current range due to leakage current. The logic circuit 1220 may monitor the low and high comparison result signals LOW_COMP, HIGH_COMP to quantify any leakage current by adjusting the amount of the second sink current I_{SNK2} generated with the adjustable current sink 1214.

At block 1304, the leakage current analyzer 1216 may determine whether the leakage current detection process has ended. The leakage current analyzer 1216 may do so in various ways. For example, the leakage current analyzer 1216 may start an overall timer when the leakage current detection process begins and monitor the time to determine when the time period expires. As another example, the leakage current analyzer may monitor the values of the digital code output from the logic circuit 1220. If the value of the digital code has stayed constant for a certain time period, the leakage current analyzer 1216 may determine that the logic circuit 1220 has finally identified or measured the amount of the leakage current I_{LKG}. Other ways that the leakage current analyzer 1216 may determine that the leakage current detection process has ended may be possible.

If the leakage current detection process has not ended, then at block 1306, the logic circuit 1220 may detect whether the source current I_{SRC} (or the first mirrored source current I_{SRC}_{_}ₘ₁) has fallen below the low reference current level I_{REF}_{_}_{MIN} based on the level of the low comparison result signal LOW_COMP. If so, then at block 1308, the logic circuit 1220 may increment the quantified current amount for the leakage current I_{LKG} by the step size. At block 1310, the logic circuit 1220 may start a timer. At block 1312, the logic circuit 1220 may detect whether the source current I_{SRC} (or the first mirrored source current I_{SRC}_{_}ₘ₁) has risen above the low reference current level I_{REF}_{_}_{MIN}. If so, then at block 1314, the logic circuit 1220 may stop the timer, and the method may proceed back to block 1302, where the leakage current detection circuit 1200 is ready to sense for and respond to changes in the leakage current I_{LKG}. Alternatively, at block 1312, if the logic circuit 1220 has not detected that the source current I_{SRC} (or the first mirrored source current I_{SRC}_{_}ₘ₁) has risen above the low reference current level I_{REF}_{_}_{MIN}, then at block 1316, the logic circuit 1220 may determine whether the time period set by the timer at block 1310 has expired. If not, then the method 1300 may proceed back to block 1312, where the logic circuit 1220 checks whether the source current I_{SRC} (or the first mirrored source current I_{SRC}_{_}ₘ₁) has risen above the low reference current level I_{REF}_{_}_{MIN}. Alternatively, at block 1316, if the time period has expired, then the method 1300 may proceed back to block 1308, where the logic circuit 1220 again increments the quantified amount of current by the step size, and starts another timer at block 1310.

Referring to block 1318, the logic circuit 1220 may also detect whether the source current I_{SRC} (or the second mirrored source current I_{SRC}_{_}ₘ₂) has risen above the high reference current level I_{REF}_{_}_{MAX} based on the level of the high comparison result signal HIGH_COMP. For example, logic circuit 1220 may first check whether the source current I_{SRC} has fallen below the low reference current level I_{REF}_{_}_{MIN}, and if not, then check whether the source current I_{SRC} has risen above the high reference current level I_{REF}_{_}_{MAX}, as indicated by the method 1300 in FIG. 13. In other example methods, the determination of whether the source current I_{SRC} has fallen below the low reference current level I_{REF}_{_}_{MIN} (block 1306) or has risen above the high reference current level I_{REF}_{_}_{MAX} (block 1318) may be concurrent determinations.

At block 1318, if the source current I_{SRC} (or the second mirrored source current I_{SRC}_{_}ₘ₂) has not risen above the high reference current level I_{REF}_{_}_{MAX}, then the method may proceed back to block 1302, where the leakage current detection circuit 1200 is ready to sense for and respond to changes in the leakage current I_{LKG}. Alternatively, if the source current I_{SRC} (or the second mirrored source current I_{SRC m2}) has not risen above the high reference current level I_{REF}_{_}_{MAX}, then at block 1318, the logic circuit 1220 may decrement the quantified current amount for the leakage current I_{LKG} by the step size. At block 1322, the logic circuit 1220 may start a timer. At block 1324, the logic circuit 1220 may detect whether the source current I_{SRC} (or the second mirrored source current I_{SRC m2}) has fallen below the high reference current level I_{REF}_{_}_{MAX}. If so, then at block 1326, the logic circuit 1220 may stop the timer, and the method may proceed back to block 1302, where the leakage current detection circuit 1200 is ready to sense for and respond to changes in the leakage current I_{LKG}. Alternatively, at block 1324, if the logic circuit 1220 has not detected that the source current I_{SRC} (or the second mirrored source current I_{SRC}_{_}ₘ₂) has fallen below the high reference current level I_{REF}_{_}_{MAX}, then at block 1328, the logic circuit 1220 may determine whether the time period set by the timer at block 1322 has expired. If not, then the method 1300 may proceed back to block 1324, where the logic circuit 1220 checks whether the source current I_{SRC} (or the second mirrored source current I_{SRC m2}) has fallen below the high reference current level I_{REF}_{_}_{MAX}. Alternatively, at block 1328, if the time period has expired, then the method 1300 may proceed back to block 1320, where the logic circuit 1220 again decrements the quantified amount of current by the step size, and starts another timer at block 1322.

Referring back to FIG. 12, when the leakage current analyzer 1216 determines that the leakage current detection process has ended, it may identify the current value of the digital code as the final value of the digital code, and in response identify the current quantified current amount indicated by the value of the digital code as the final quantified current amount for the leakage current I_{LKG}. The leakage current analyzer 1216 may be configured to compare the final quantified current amount with a predetermined leakage current threshold level, and output a result signal RSLT that indicates whether final quantified current amount is below or exceeded the leakage current threshold level. The leakage current analyzer 1216 may output the result signal RSLT to the control logic 154 (FIG. 2B) that is configured to determine a next process based on the result signal RSLT.

If the leakage current detection circuit 1200 performed the leakage current detection process for a single block—e.g., the voltage generated and regulated on node A is supplied to only one block—the control logic 154 may determine a usability status of that block based on the result signal RSLT. In particular, if the result signal RSLT indicates that the quantified current amount is below the leakage current threshold, then the control logic 154 may determine that the block is usable. If a memory operation was concurrently performed during the leakage current detection process, an associated event of the memory operation may support the result of the leakage current detection process. For example, if the memory operation is a read operation to read data, successful decoding of the data performed by the ECC engine 124 (FIG. 2A) may support the result signal's indication that the quantified current amount is below the leakage current threshold. As another example, if the memory operation is a program-verify operation, a successful enhanced program write read (EPWR) operation may support the result signal's indication that the quantified current amount is below the leakage current threshold.

Alternatively, if the result signal RSLT indicates that the quantified current amount is above or has exceeded the leakage current threshold, then the control logic 154 may determine that the block is unusable, either immediately or in the near future. In some situations, the control logic 154 may notify or report the result of the leakage current detection process to the controller 102 (FIG. 2A), and the media management layer 138 (FIG. 2A) may determine a new block. For example, if data is currently being stored in the block, then the media management layer 138 may identify a new block into which to program the data. Alternatively, if the concurrent memory operation is a program-verify operation, the media management layer 138 may determine a new block into which to program the data. In other example configurations, the control logic 154 on the memory die 154 may determine the new block without communicating with the controller 102. However, the control logic 154 may still need to communicate with the controller 102 for addressing purposes.

As previously described, the peripheral circuitry 152, with the read/write circuitry 144, may be configured to perform concurrent memory operations for memory cells connected to shared word lines of the same set. For example, as previously described with reference to FIG. 12, the leakage detection circuit 1200, with its voltage generation circuit, may be configured to concurrently or simultaneously supply the selected word line voltage V_{SWL} generated at node A to the first selected word line WLX(S) for performance of a first memory operation associated with the first selected word line WLX(S), and to the second selected word line WLY(S) for performance of a second memory operation associated with the second selected word line WLY(S). The leakage current detection circuit 1200 may perform a leakage current detection process concurrently with the first memory operation and the second memory operation.

Where the leakage current detection process is performed for two or more blocks and/or concurrently with two or more concurrently-performed memory operations, in the event that the control logic 154 determines that the measured current amount (e.g, the final quantified current amount) for the leakage current I_{LKG} is above the leakage current threshold, the control logic 154 would not know which of the blocks has a defective word line. For example, with reference to FIG. 12, the control logic 154 would not know whether the first block 1202(1) has a defective word line, the second block 1202(2) has a defective word line, or both have a defective word line.

In this situation, the control logic 154 may output the control signal CTRL to the WL switching circuit 1206 to isolate the first and second blocks 1202(1), 1202(2) from each other, and repeat the leakage current detection process for one or both of the first and second blocks 1202(1), 1202(2). In response to receipt of the control signal CTRL, the WL switching circuit 1206 is configured to isolate the first and second blocks 1202(1), 1202(2) from each other. By isolating the first and second blocks 1202(1), 1202(2) from each other, one the selected word lines WLX(S), WLY(S) of one of the blocks 1202(1), 1202(2) is electrically connected to node A and configured to receive the voltage generated with the leakage detection circuit 1200 at node A, and the other of the word lines WLX(S), WLY(S) of the other of the blocks 1202(1), 1202(2) is not.

Accordingly, when the leakage detection process is repeated and the two blocks 1202(1), 1202(2) are isolated from each other, the WL switching circuit 1206 will supply the voltage it receives from the voltage supply line 1204 to only one of the selected word lines WLX(S), WLY(S) and not the other. Upon repeating the leakage current detection process for one or both of the blocks 1202(1), 1202(2) in isolation, the leakage current analyzer 1216 can generate a result signal RSLT indicating whether a quantified current amount of leakage current is above or below the leakage current threshold for a single block. The control logic 154 can then make a usability status determination for each of the blocks 1202(1), 1202(2).

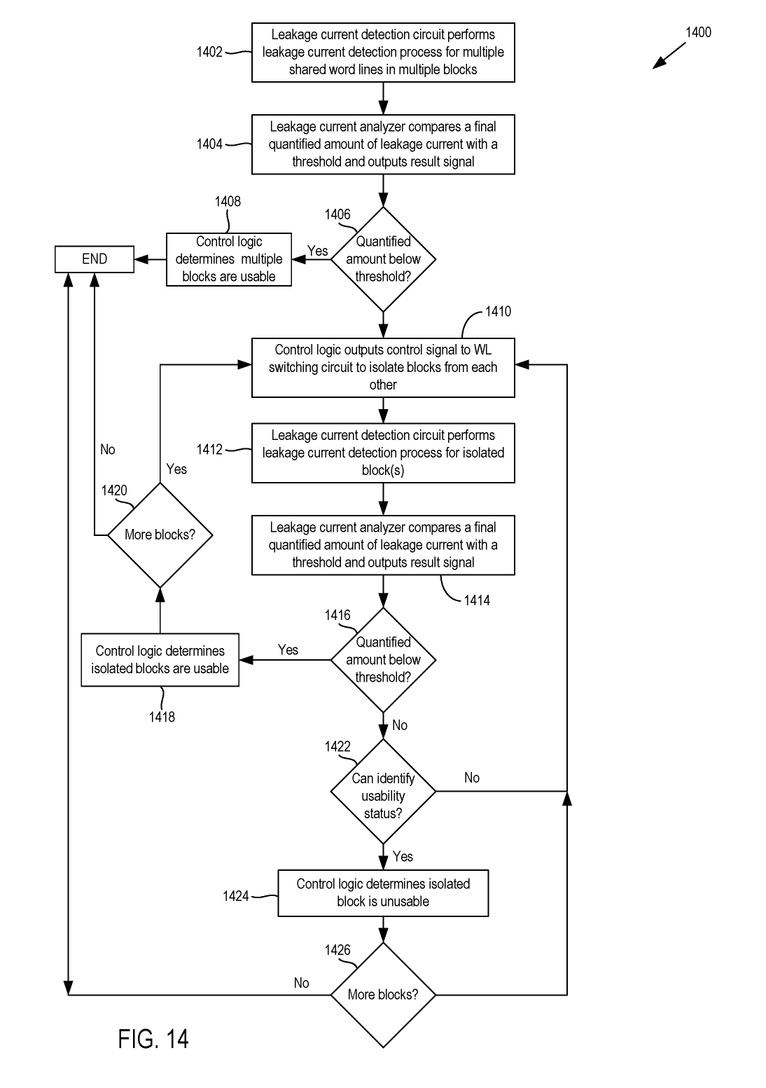

FIG. 14 is a flow chart of an example method 1400 of determining usability statuses based on leakage current detection for a plurality of blocks having shared word lines. At block 1402, the leakage current detection block 1200 may perform a leakage current detection process, such as the process described with reference to FIG. 13, for the plurality of blocks. The leakage current detection circuit 1200 may do so by supplying a voltage, such as a selected word line voltage to a word line in each of the blocks. In some example methods, the leakage current detection process performed at block 1402 may be performed concurrently with a plurality of memory operations (e.g., a plurality of read operations, a plurality of program operations, or a plurality of verify operations) for memory cells connected to the word lines receiving the voltage from the leakage current detection circuit 1200.

At block 1402, the leakage current detection process may end and the leakage current analyzer 1216 may compare a final quantified current amount of leakage current with a leakage current threshold, and output a result signal RSLT indicative of the comparison to the control logic 154. At block 1406, the control logic 154 may identify whether the quantified amount of leakage current I_{LKG} is above or below the leakage current threshold. If it below the leakage current threshold, then at block 1408, the control logic 154 may determine that all of the plurality of blocks subject to the leakage current detection test are usable, and the method 1400 may end.

Alternatively, at block 1406, if the control logic 154 determines that the quantified amount of leakage current I_{LKG} is above the leakage current threshold, then at block 1410, the control logic 154 may output the control signal CTRL to the WL switching circuit 1206 to isolate one or more blocks and associated shared word lines from each other so that some of the blocks and their word lines are in electrical communication with and configured to receive the voltage from the leakage current detection circuit 1200 and others are not. The control logic 154 may output the control signal CTRL to the WL switching circuit 1206 in various ways to isolate the blocks and associated shared word lines. For situations involving two blocks, such as the first block 1202(1) and the second block 1202(2) shown in FIG. 12, the control logic 154 may output the control signal CTRL so that the WL switching circuit 1206 connects one of the selected word lines WLX(S), WLY(S) to the leakage current detection circuit 1200 and disconnects the other of the selected word lines WLX(S), WLY(S) from the leakage current detection circuit 1200, so that only one of the selected word lines WLX(S), WLY(S) is configured to receive the voltage from the leakage current detection circuit 1200.

For situations involving more than two blocks, the control logic 154 may output the control signal CTRL to the WL switching circuit 1206 to isolate the blocks and associated shared word lines from each other in various ways. In one example, the control logic 154 may select only one block at a time to receive the voltage from the leakage detection circuit 1200 in a next leakage current detection process. In other examples, the control logic 154 may configure the WL switching circuit 1206 so that two but less than all of the shared word lines are configured to receive the voltage in a next leakage current detection process. To illustrate, suppose the WL switching circuit 1206 can be configured to simultaneously connect four word lines in four different blocks to the leakage current detection circuit 1200. In the event that the control logic 154 determines the quantified current amount for the leakage current to be above the leakage current threshold at block 1406, the control logic 154 may output the control signal CTRL to configure the WL switching circuit 1206 so that two of the word lines are configured to receive the voltage from the leakage current detection circuit 1200 and two are not during the next leakage current detection process. Various ways of isolating the blocks and associated shared word lines from each other may be possible.

At block 1412, the leakage current detection circuit 1200 is configured to perform another leakage current detection process, this time for the selected word lines of the isolated block(s) that is/are configured to receive the voltage from the leakage current detection circuit 1200, and not for those that are not configured to receive the voltage from the leakage current detection circuit 1200. At block 1414, the leakage current analyzer 1216 compares a final quantified current amount of leakage current with a leakage current threshold level and outputs its result signal RSLT, indicating the result of the comparison, to the control logic 154.

At block 1416, the control logic 154 determines whether quantified current amount is below the leakage current threshold? If it is, then at block 1418, the control logic 154 may determine that the isolate(d) blocks for which the last leakage current detection process was performed at block 1412 are usable. At block 1420, the control logic 154 may determine whether it needs to identify a usability status for any more of the plurality of blocks. If not, then the method 1400 may end. If so, then the method 1400 may proceed back to block 1410, where the control logic outputs the control signal CTRL to the WL switching circuit 1206 to isolate the blocks from each other so that at least one of the word lines is configured to receive the voltage from the leakage detection circuit 1200 in a next leakage current detection process performed at block 1412.

Referring back to block 1416, if the control logic 154 determines that the quantified amount of current is not below the leakage current threshold, then at block 1422, the control logic 154 may determine if is able to determine the usability status of the block or blocks even though the quantified current amount was above the leakage current threshold. If two or more word lines received the voltage from the leakage current detection circuit 1200 during the leakage current detection process performed at block 1412, then the control logic 154 may determine that it is unable to determine the usability status. Accordingly, the method may proceed back to block 1410, where the control logic 154 outputs the control signal CTRL to the WL switching circuit 1206 to isolate the blocks and associated word lines from each other. Alternatively, at block 1422, if only a single word lines received the voltage from the leakage current detection circuit 1200 at block 1412, then at block 1424, the control logic 154 may determine that it can identify the usability status of the single block, and in particular, identify the block as being unusable. The control logic 154 may take further steps to ensure that proper action is taken, such as by choosing a different block in which to program data or moving data to a different block as examples. At block 1426, the control logic 154 may determine whether it needs to identify a usability status for any more of the plurality of blocks. If so, then the method may proceed back to block 1410, where the control logic 154 outputs the control signal CTRL to the WL switching circuit 1206 to isolate the blocks and associated word lines from each other. If not, then the method 1400 may end.

It is intended that the foregoing detailed description be understood as an illustration of selected forms that the invention can take and not as a definition of the invention. It is only the following claims, including all equivalents, that are intended to define the scope of the claimed invention. Finally, it should be noted that any aspect of any of the preferred embodiments described herein can be used alone or in combination with one another.

1. A circuit comprising:
a voltage generation circuit configured to:
generate a voltage supplied to a word line of a memory array via a voltage supply path; and
a measurement circuit configured to:
measure an amount of leakage current sourced to a node connected to the voltage supply path during supply of the voltage to the word line; and
control an adjustable current sink to sink, from the node, an amount of sink current corresponding to the measured amount of the leakage current in discrete steps; and
keep track of the adjustments to measure the amount of the leakage current.

2. The circuit of claim 1, wherein the voltage generation circuit is further configured to:
supply a source current to the node; and
regulate the voltage through adjustment of the level of the source current.

3. The circuit of claim 1, wherein the measurement circuit is configured to:
control the adjustable current sink to maintain a level of the source current in a target current range; and
determine how much the adjustable current sink adjusted the sink current to keep the source current in the target current range in order to measure the amount of leakage current.

4. The circuit of claim 1, further comprising:
a sense circuit configured to:
sense an amount of the leakage current; and
generate at least one sense current indicative of the amount of the leakage current,
wherein the measurement circuit is configured to measure the amount of the leakage current in response to the at least one sense current.

5. The circuit of claim 4, wherein the measurement circuit is further configured to:
compare the at least one sense current to a high reference current level and a low reference current level; and
measure the amount of the leakage current in response to the comparison.

6. The circuit of claim 5, wherein the measurement circuit is further configured to:
control the adjustable current sink to increment and decrement the sink current in discrete step sizes in response to the comparison; and
keep track of the incrementing and decrementing to measure the amount of the leakage current.

7. (canceled)

8. The circuit of claim 1, further comprising a control circuit configured to identify that the leakage current has exceeded a threshold in response to the measurement of the amount of the leakage current.

9. The circuit of claim 1, further comprising a control circuit configured to identify a usability status of a block comprising the word line in response to the measured amount of leakage current.

10. A circuit comprising:
a feedback path configured to change a level of a feedback voltage in response to a leakage current
a voltage regulation circuit configured to:
supply a source current to a node for generation of a voltage supplied to a selected word line;
receive the feedback voltage; and
adjust the source current in response to the change in the level of the feedback voltage in order to regulate the voltage to a selected word line level;
a sense circuit configured to:
sense an adjustment of a level of the source circuit current; and
generate at least one sense current indicative of the adjustment; and
a measurement circuit configured to:
measure an amount of the leakage current in response to the at least one sense current.

11. The circuit of claim 10, wherein the sense circuit comprises a current mirror circuit configured to mirror the source current to generate the at least one sense current.

12. The circuit of claim 11, wherein the measurement circuit comprises:
a comparison circuit configured compare the at least one sense current to a high reference current level and a low reference current level; and
a logic circuit configured to adjust a quantified current amount of the leakage current based on the comparison.

13. The circuit of claim 12, wherein the logic circuit is further configured to:
control an adjustable current sink to maintain the source current between the high reference current level and the low reference current level; and
determine the quantified current amount based on the control of the adjustable current sink.

14. The circuit of claim 13, wherein the logic circuit is configured to control the adjustable current sink in discrete steps.

15. The circuit of claim 10, further comprising a control circuit configured to identify that the leakage current has exceeded a threshold in response to the measurement of the amount of the leakage current.

16. A system comprising:
a memory comprising a first block and a second block;
a voltage generation circuit configured to concurrently supply a voltage to a first word line of the first block for performance of a first memory operation, and to a second word line of the second block for performance of a second memory operation; and
a word line switching circuit configured to:
isolate the first word line and the second word line from each other in response to a first amount of leakage current exceeded the exceeding a leakage current threshold; and
supply the voltage to only one of the first word line and the second word line in response to the isolation of the first word line and the second word line from each other,
a control circuit configured to:
determine that the first amount of leakage current exceeds the leakage current threshold; and
identify a usability status for each of the first block and the second block in response to the isolation of the first word line and the second word line from each other; and
a measurement circuit configured to:
measure the first amount of leakage current generated during the concurrent supply of the voltage to the first word line and the second word line; and
measure a second amount of leakage current generated during supply of the voltage to only one of the first word line and the second word line in response to the isolation of the first word line and the second word line from each other.

17. The system of claim 16, wherein the voltage generation circuit is configured to supply a source current to a node to generate the voltage, and
wherein the measurement circuit is further configured to:
control an adjustable current sink to maintain the source current within a target current range during supply of the voltage to the first word line and the second word line; and
keep track of adjustments to a sink current generated with the adjustable current sink to measure the amount of the leakage current.

18. The system of claim 17, wherein the voltage generation circuit comprises a feedback path to adjust the source current.

19. The system of claim 17, further comprising:
a sense circuit configured to:
sense an adjustment of a level of the source current; and
generate at least one sense current indicative of the adjustment,
wherein the measurement circuit is configured to measure the amount of the leakage current based on the at least one sense current.

20. The system of claim 16, wherein the voltage generation circuit is configured to concurrently supply the voltage to the first word line and to the second word line in response to one or more host commands to read or write data to memory cells connected to the first word line and to the second word line.
